(19) United States
(12) Patent Application Publication
(10) Pub. No.: US 2024/0321497 A1
(43) Pub. Date: Sep. 26, 2024

(54) INTEGRATED DEVICE COMPRISING A PAIR OF INDUCTORS WITH LOW OR NO MUTUAL INDUCTANCE

(71) Applicant: QUALCOMM Incorporated, San Diego, CA (US)

(72) Inventors: Hsiao-Tsung YEN, San Diego, CA (US); Xingyi HUA, San Diego, CA (US); Jeongil Jay KIM, San Diego, CA (US)

(21) Appl. No.: 18/189,910

(22) Filed: Mar. 24, 2023

(51) Int. Cl. H01F 17/00; H01L 23/498

(52) U.S. Cl. CPC H01F 17/0013; H01L 23/49822; H01L 28/10; H01F 2017/002; H01F 2017/0086; H01L 24/16; H01L 2224/16227

(57) ABSTRACT

An integrated device comprising a die substrate; and a die interconnection portion coupled to the die substrate. The die interconnection comprises a first inductor and a second inductor. The first inductor comprises a first spiral comprising a first origin and a first tail and a second spiral comprising a second origin and a second tail.

### FIELD Various features relate to integrated devices with inductors.

### BACKGROUND

A package may include a substrate and integrated devices. These components are coupled together to provide a package that may perform various functions. The performance of a package and its components may depend on how these components are configured together. Several inductors may be configured to be electrically coupled to an integrated device. These inductors can take up a lot of real estate in the package, which can limit how small an integrated device and/or a package can be. There is an ongoing need to provide integrated devices and/or package with smaller form factors, while improving the performance of the integrated devices and/or the package.

### SUMMARY

Various features relate to integrated devices with inductors.

One example provides an integrated device that includes a die substrate; and a die interconnection portion coupled to the die substrate. The die interconnection comprises a first inductor and a second inductor. The first inductor comprises a first spiral comprising a first origin and a first tail and a second spiral comprising a second origin and a second tail.

Another example provides a device that comprises a first inductor and a second inductor. The first inductor comprises a first spiral comprising a first origin and a first tail and a second spiral comprising a second origin and a second tail. The first spiral and the second spiral form a figure 8-shaped inductor.

Another example provides a method for fabricating an integrated device. The method provides a die substrate. The method forms a die interconnection portion coupled to the die substrate, wherein forming the die interconnection portion includes forming a plurality of die interconnects. The plurality of die interconnects comprises a first plurality die interconnects that define a first inductor . The first inductor comprises a first spiral comprising a first origin and a first tail; and a second spiral comprising a second origin and a second tail; and a second plurality of die interconnects that define a second inductor.

Another example provides a method that provides a die substrate. The method forms a die interconnection portion coupled to the die substrate, wherein forming the die interconnection portion includes forming a plurality of die interconnects. The plurality of die interconnects comprises a first plurality interconnects that define a first inductor . The first inductor comprises a first spiral comprising a first origin and a first tail; and a second spiral comprising a second origin and a second tail. The method forms a metallization portion that comprises a plurality of metallization interconnects, wherein the plurality of metallization interconnects comprises a first plurality of metallization interconnects that define a second inductor.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile cross sectional view of an exemplary package that includes an integrated device and a package substrate

FIG. 2 illustrates an exemplary view of two inductors, where one of the inductors includes a first spiral and a second spiral.

FIG. 3 illustrates an exemplary view of an inductor that includes a first spiral and a second spiral.

FIG. 4 illustrates an exemplary assembly view of an inductor that includes a first spiral and a second spiral.

FIG. 5 illustrates an exemplary view of an inductor.

FIG. 6 illustrates exemplary views of two inductors, where one of the inductors includes a first spiral and a second spiral.

FIG. 7 illustrates a profile cross sectional view of an exemplary integrated device that can include two inductors, where one of the inductors includes a first spiral and a second spiral.

FIG. 8 illustrates a profile cross sectional view of an exemplary package that includes an integrated device and a metallization portion, where the package can include two inductors, and where one of the inductors includes a first spiral and a second spiral.

FIG. 9 illustrates exemplary views of two inductors, where one of the inductors includes a first spiral and a second spiral.

FIG. 10 illustrates exemplary views of two inductors, where one of the inductors includes a first spiral and a second spiral.

FIG. 11 illustrates exemplary views of two inductors, where one of the inductors includes a first spiral and a second spiral.

FIG. 12 illustrates exemplary views of two inductors, where one of the inductors includes a first spiral and a second spiral.

FIG. 13 illustrates exemplary views of two inductors, where one of the inductors includes a first spiral and a second spiral.

FIGS. 14A-14C illustrate an exemplary sequence for fabricating an integrated device.

FIG. 15 illustrates an exemplary flow diagram of a method for fabricating an integrated device.

FIGS. 16A-16D illustrate an exemplary sequence for fabricating a package.

FIG. 17 illustrates an exemplary flow diagram of a method for fabricating a package.

FIG. 18 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

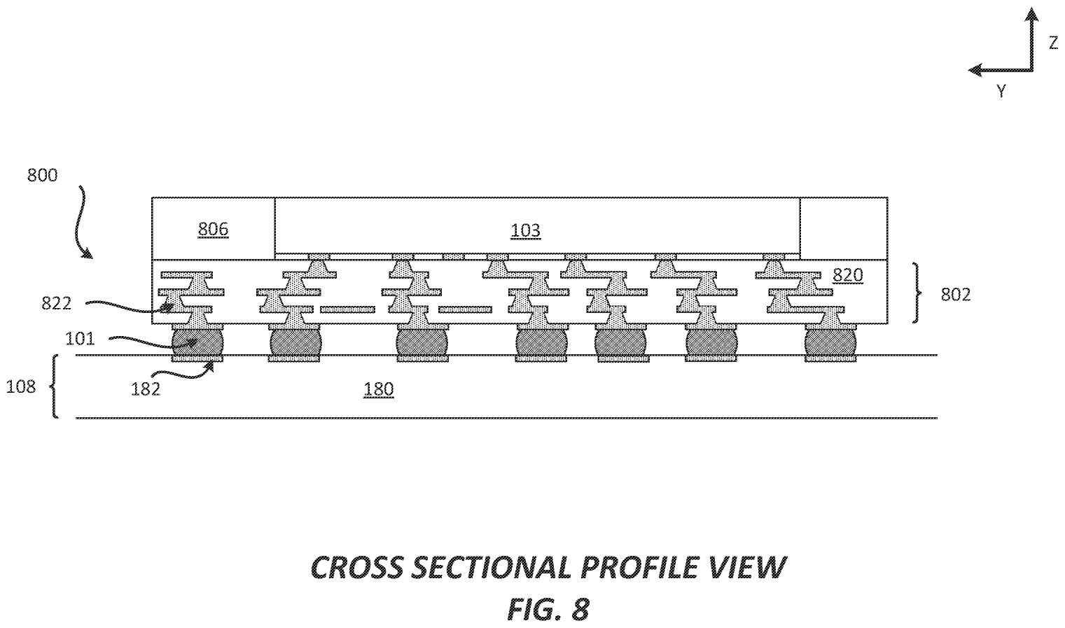

The present disclosure describes a package that includes a first inductor and a second inductor. The first inductor includes a first spiral and a second spiral. The first spiral includes a first origin and a first tail. The second spiral includes a second origin and a second tail. The first inductor may be configured as a figure 8-shaped inductor. The first inductor and the second inductor may have a mutual inductance of zero (0) or near zero. The first inductor and the second inductor may have a mutual inductance (e.g., coefficient of coupling K) in a range of about 0-0.1. Thus, there may be little or no mutual inductance between the first inductor and the second inductor. The first inductor may be located above or below the second inductor. The first inductor may be located laterally around the second inductor. The first inductor and the second inductor may be implemented in an integrated device of a package that includes the integrated device. In some implementations, the first inductor and the second inductor may be implemented in the die interconnection portion of an integrated device. In some implementations, the first inductor and the second inductor may be implemented in a die interconnection portion and/or a metallization portion (e.g., redistribution portion) of an integrated device. In some implementations, the first inductor and the second inductor may be implemented in an integrated device and a package substrate of a package. The use of a first spiral and a second spiral in the first inductor helps provide an inductor with little or no mutual inductance with an adjacent second inductor, while still providing a high Q factor inductor. Moreover, the use of a first spiral and a second spiral in the first inductor helps provide an inductor with a high inductance, while having a small form factor. Thus, the first inductor with a first spiral and a second spiral may provide an inductance that is similar to an inductance of a comparable inductor that is larger in size than the first inductor.

### Exemplary Package Comprising a Pair of Inductors

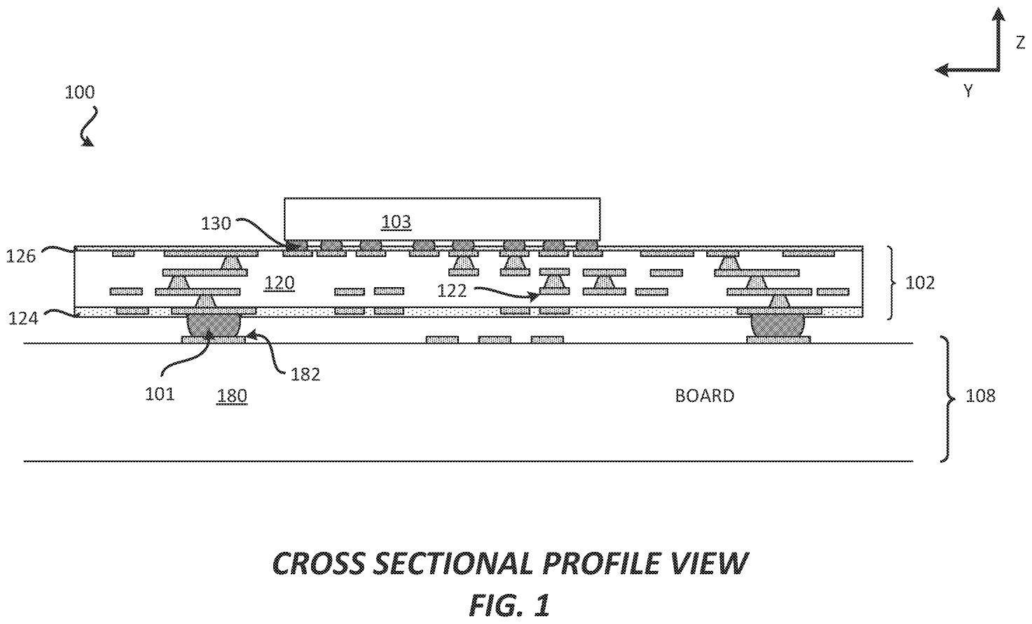

FIG. 1 illustrates a profile cross sectional view of a package 100 that includes a substrate 102 and an integrated device 103. The package 100 is coupled to a board 108 (e.g., printed circuit board) through a plurality of solder interconnects 101. The board 108 includes at least one board dielectric layer 180 and a plurality of board interconnects 182. The package 100 is coupled to the plurality of board interconnects 182 of the board 108 (e.g., printed circuit board) through the plurality of solder interconnects 101. The plurality of solder interconnects 101 may be coupled to board interconnects from the plurality of board interconnects 182.

The substrate 102 may be a package substrate. The substrate 102 includes a first surface (e.g., top surface) and a second surface (e.g., bottom surface). The substrate 102 includes at least one dielectric layer 120 (e.g., at least one substrate dielectric layer) and a plurality of interconnects 122 (e.g., plurality of substrate interconnects). The at least one dielectric layer 120 may include prepreg. In some implementations, the first surface of the substrate 102 includes a solder resist layer 126 and the second surface of the substrate 102 includes a solder resist layer 124. The substrate 102 may be a laminate substrate. Different implementations may use different types of substrates. Different implementations may use different materials for the at least one dielectric layer 120. The plurality of solder interconnects 101 may be coupled to interconnects from the plurality of interconnects 122.

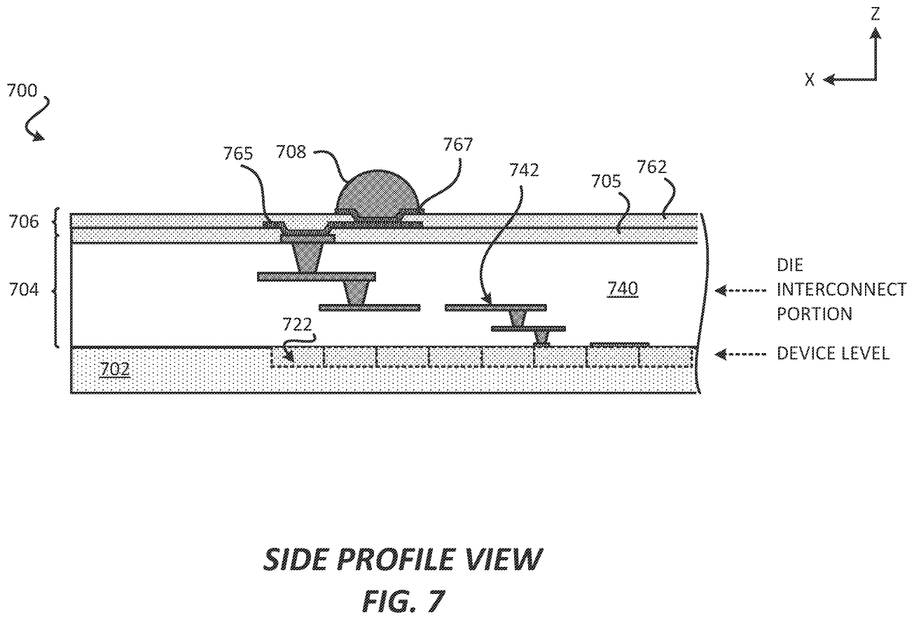

The integrated device 103 is coupled to the first surface (e.g., top surface) of the substrate 102 through a plurality of solder interconnects 130. For example, the integrated device 103 may be coupled to the substrate 102 through a plurality of pillar interconnects (not shown) and the plurality of solder interconnects 130. The plurality of solder interconnects 130 may be coupled to one or more interconnects from the plurality of interconnects 122. The integrated device 103 includes a front side and a back side. The front side of the integrated device 103 faces the substrate 102. Different implementations may use different types of integrated devices. An example of an integrated device is illustrated and described below in at least FIG. 7.

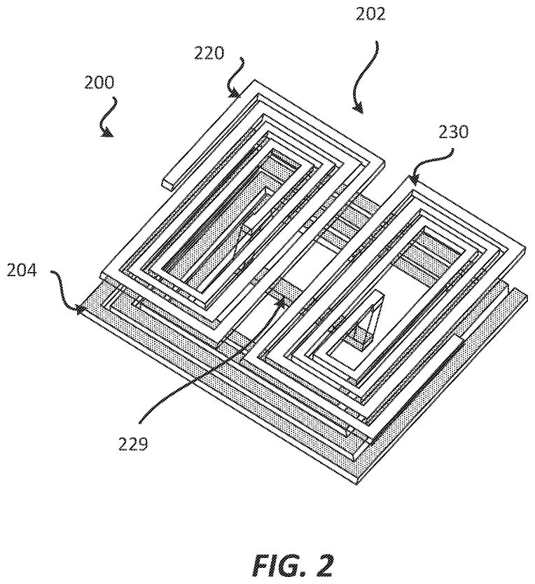

As will be further described below, a first inductor and a second inductor may be implemented in the package 100. The first inductor and the second inductor may be a pair of inductors that have a mutual inductance of zero (0) or near zero. The first inductor and the second inductor may have a mutual inductance (e.g., coefficient of coupling K) in a range of about 0-0.1. The first inductor may include a first spiral and a second spiral. The second inductor may include a spiral inductor. The first inductor and/or the second inductor may be implemented as interconnects (i) on the metal layer(s) of the integrated device 103, (ii) on the metal layer(s) of the substrate 102, (iii) between metal layers of the integrated device 103, and/or (iv) between metal layers of the substrate 102. In some implementations, some solder interconnects of the solder interconnects 130 may be considered part of the first inductor and/or the second inductor. In some implementations, some solder interconnects of the solder interconnects 101 may be considered part of the first inductor and/or the second inductor. In some implementations, the first inductor may be located above or below the second inductor. In some implementations, a first portion of the first inductor may be located above the second inductor, and a second portion of the first inductor may be located below the second inductor. In some implementations, the first inductor may be located above and below the second inductor. In some implementations, the first inductor may be coupled to the second inductor in shunt or series. In some implementations, the first inductor may laterally surround the second inductor. The first inductor and the second inductor may provide high inductance values while occupying a much smaller footprint and/or real estate in the package. This allows the package and/or the integrated device to have a smaller lateral area through the sharing of lateral space and/or vertical stacking with one another, without sacrificing and/or diminishing the performance of the package and/or the integrated device. In some implementations, at one or more turns of the first inductor vertically overlaps with the second inductor. FIGS. 2-6 and 9-13 illustrate examples of different configurations of inductors and/or different inductor combinations that may be implemented in a package, an integrated device and/or a substrate.

FIG. 2 illustrates an inductor 202 and an inductor 204. In some implementations, the inductor 202 may be a first inductor and the inductor 204 may be a second inductor. In some implementations, the inductor 204 may be a first inductor and the inductor 202 may be a second inductor. The inductor 202 and the inductor 204 may be part of a pair of inductors 200. The pair of inductors 200 may be configured to operate as a transformer. Thus, in some implementations, the inductor 202 and the inductor 204 may be configured to operate as a transformer. In some implementations, a current traveling through the inductor 202 may induce a current in the inductor 204. In some implementations, a current traveling through the inductor 204 may induce a current in the inductor 202.

The inductor 202 is located above the inductor 204. However, in some implementations, the inductor 202 may be located below the inductor 204. The inductor 202 vertically overlaps with the inductor 204, and vice versa. The inductor 204 includes a spiral. The inductor 204 may be a spiral inductor. The inductor 202 includes a first spiral 220 and a second spiral 230. The first spiral 220 of the inductor 202 may be coupled to the second spiral 230 of the inductor 202 through at least one inductor interconnect 229. The inductor 202 may be configured as figure 8-shaped inductor. As will be further described below, the inductor 202, the inductor 204 and/or any of the inductors described in the disclosure may have different designs, including different spirals, different numbers of turns, different windings, and/or different crossings. The number of turns in the spiral in the inductors shown in the disclosure are exemplary. Different implementations may have inductors with spirals that have different numbers of turns. The designs of the inductors are not limited to what is shown in the figures of the disclosure. Different implementations may have different designs to form symmetrical inductors to achieve a mutual inductance of zero (0) or near zero.

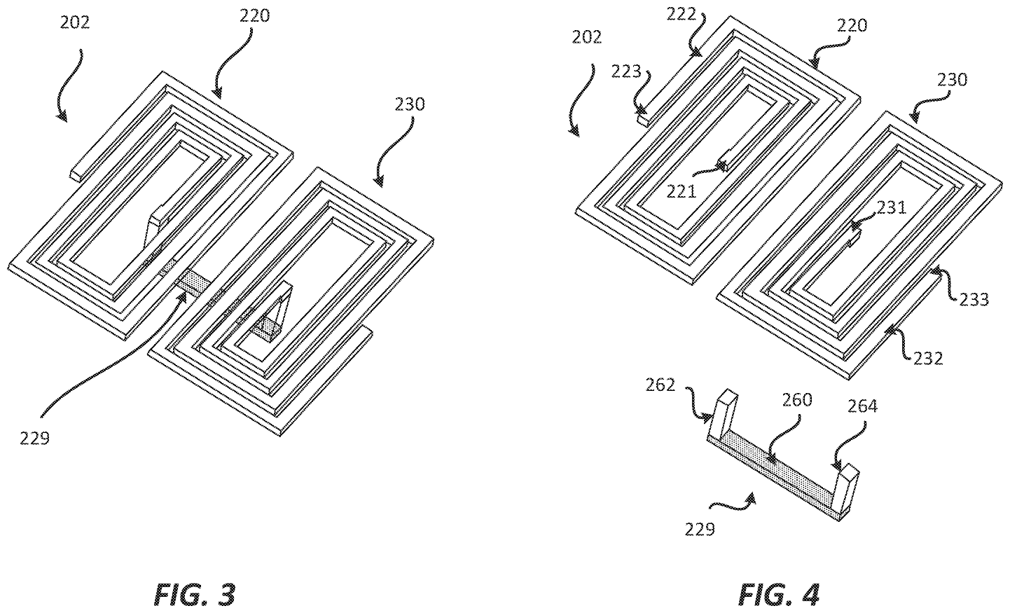

FIGS. 3 and 4 illustrate the inductor 202 that includes the first spiral 220, the second spiral 230 and the at least one inductor interconnect 229. The first spiral 220 and the second spiral 230 may be located on a same metal layer. The at least one inductor interconnect 229 may be located on a different metal layer than the metal layer on which the first spiral 220 and the second spiral 230 are located.

The inductor 202 includes a first spiral 220. The first spiral 220 may include a first origin 221, a first tail 222 and a first tail terminal 223. The first origin 221 may be a first nucleus of the first spiral 220. The first origin 221 may be a first terminal for the first spiral 220. The first tail terminal 223 may be a second terminal for the first spiral 220. The first spiral 220, the first origin 221, the first tail 222 and the first tail terminal 223 may be defined by one or more first spiral interconnects. For example, a first spiral interconnect may define and/or represent the first spiral 220. A first portion of the first spiral interconnect may represent the first origin 221. A second portion of the first spiral interconnect may represent the first tail 222. A third portion of the first spiral interconnect may represent the first tail terminal 223. In some implementations, the first spiral 220 may have a first rotational direction (e.g., counter clockwise). In some implementations, the first spiral 220 may have another rotational direction (e.g., clockwise rotation). A rotational direction of a spiral may be defined by the origin of the spiral as being the starting point of the spiral.

The inductor 202 includes a second spiral 230. The second spiral 230 may include a second origin 231, a second tail 232 and a second tail terminal 233. The second origin 231 may be a second nucleus of the second spiral 230. The second origin 231 may be a first terminal for the second spiral 230. The second tail terminal 233 may be a second terminal for the second spiral 230. The second spiral 230, the second origin 231, the second tail 232 and the second tail terminal 233 may be defined by one or more second spiral interconnects. For example, a second spiral interconnect may define and/or represent the second spiral 230. A first portion of the second spiral interconnect may represent the second origin 231. A second portion of the second spiral interconnect may represent the second tail 232. A third portion of the second spiral interconnect may represent the second tail terminal 233. In some implementations, the second spiral 230 may have a first rotational direction (e.g., counter clockwise). In some implementations, the second spiral 230 may have another rotational direction (e.g., clockwise rotation).

The inductor 202 and the inductor 204 are each approximately the same in terms of footprint. However, the inductor 202 and the inductor 204 may have different footprints. Both the inductor 202 and the inductor 204 have spirals that form a rectangular shape. However, different implementations of the inductor 202 and/or the inductor 204 may have spirals with other shapes, such as a circle, an oval, a square, and/or an octagon.

The first spiral 220 is coupled to the second spiral 230 through the at least one inductor interconnect 229. The inductor interconnect 229 may include an inductor via 262, an inductor trace 260 and an inductor via 264. The inductor via 262 may be coupled to (i) the first origin 221 of the first spiral 220 and (ii) the inductor trace 260. The inductor via 264 may be coupled to (i) the second origin 231 of the second spiral 230 and (ii) the inductor trace 260.

In some implementations, instead of a via and/or in conjunction of a via, solder interconnects and/or pillar interconnects may be used to couple the first spiral 220 and the second spiral 230. As will be further described below, the inductor vias may be implanted as through substrate vias (e.g., through silicon vias), die vias, substrate vias, metallization vias, under bump metallization vias, and/or redistribution vias.

In some implementations, an electrical current may travel through the inductor 202 through an electrical path that includes the first tail terminal 223, the first tail 222, the first origin 221, the inductor via 262, the inductor trace 260, the inductor via 264, the second origin 231, the second tail 232 and the second tail terminal 233. In some implementations, a current may enter through the first tail terminal 223 and exit through the second tail terminal 233. In some implementations, a current may enter through the second tail terminal 233 and exit through the first tail terminal 223.

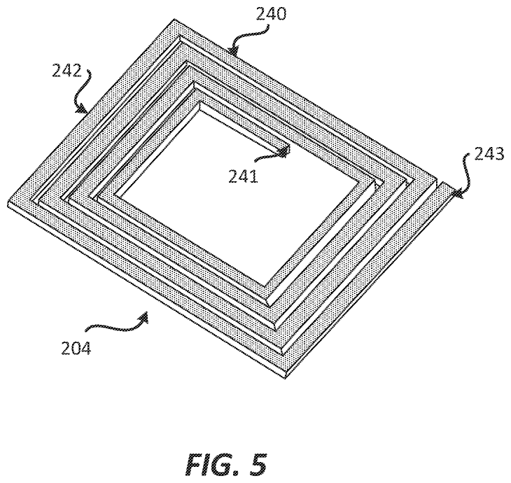

FIG. 5 illustrates the inductor 204 that includes a spiral 240. The spiral 240 includes an origin 241, a tail 242 and a tail terminal 243. The origin 241 may be a nucleus of the spiral 240. The origin 241 may be a first terminal for the inductor 204. The tail terminal 243 may be a second terminal for the inductor 204. The spiral 240, the origin 241, the tail 242 and the tail terminal 243 may be defined by one or more spiral interconnects. For example, a spiral interconnect may define and/or represent the spiral 240. A first portion of the spiral interconnect may represent the origin 241. A second portion of the spiral interconnect may represent the tail 242. A third portion of the spiral interconnect may represent the tail terminal 243. In some implementations, the spiral 240 may have a first rotational direction (e.g., counter clockwise). In some implementations, the spiral 240 may have another rotational direction (e.g., clockwise rotation).

In some implementations, an electrical current may travel through the inductor 204 through an electrical path that includes the tail terminal 243, the tail 242, and the origin 241. In some implementations, a current may enter through the tail terminal 243 and exit through the origin 241. In some implementations, a current may enter through the origin 241 and exit through the tail terminal 243.

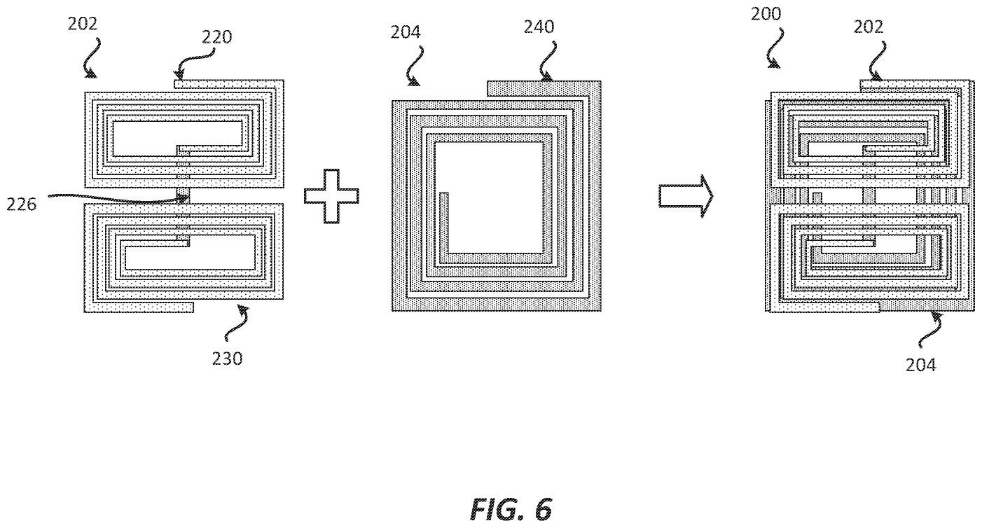

FIG. 6 illustrates plan views of the inductor 202 and the inductor 204. As shown in FIG. 6, the inductor 202 may vertically overlap with the inductor 204. The combination of the inductor 202 and the inductor 204 may be configured to operate as a transformer. The first spiral 220 and the second spiral 230 of the inductor 202 may be located on a first metal layer. The spiral 240 of the inductor 204 may be located on a different metal layer (e.g., second metal layer) than the first metal layer. As mentioned above, the inductor 202 and the inductor 204 may be implemented in a package. For example, the inductor 202 and the inductor 204 may be implemented in metal layers of an integrated device of a package. In some implementations, the inductor 202 and the inductor 204 may be implemented in the metal layers of a substrate. In some implementations, the inductor 202 and the inductor 204 may be implemented in the metal layers of an integrated device and/or metal layers of a substrate.

FIG. 7 illustrates a cross sectional profile view of an integrated device 700. The integrated device 700 may represent the integrated device 103 of FIG. 1. The integrated device 700 includes a die substrate 702, an interconnection portion 704, a metallization portion 706. A plurality of solder interconnects 708 may be coupled to the metallization portion 706. The interconnection portion 704 may be a die interconnection portion.

The die substrate 702 may include silicon (Si). A plurality of cells (e.g., logic cells) and/or a plurality of transistors (not shown) may be formed in and/or over the die substrate 702. The plurality of cells (e.g., logic cells) and/or a plurality of transistors (not shown) may be part of the device level 722 of the integrated device 700. Different implementations may use different types of transistors, such as a field effect transistor (FET), planar FET, finFET, and a gate all around FET. In some implementations, a front end of line (FEOL) process may be used to fabricate the plurality of cells (e.g., logic cells) and/or transistors in and/or over the die substrate 702. Although not shown, the die substrate 702 may include through substrate vias. Moreover, one or more metal layers (not shown and which may form back side interconnects) may be coupled to the back side of the die substrate 702. These back side interconnects may be coupled to the through substrate vias. The interconnection portion 704 is located over and coupled to the die substrate 702. The interconnection portion 704 may be coupled to the plurality of cells and/or transistors located in and/or over the die substrate 702. The interconnection portion 704 (e.g., die interconnection portion) may include at least one dielectric layer 740 (e.g., die dielectric layer) and a plurality of die interconnects 742. The plurality of die interconnects 742 may be coupled to the plurality of cells and/or transistors. In some implementations, a back end of line (BEOL) process may be used to fabricate the interconnection portion 704. The interconnection portion 704 may include a passivation layer 705. The passivation layer 705 may be located over the at least one dielectric layer 740.

The metallization portion 706 is coupled to the interconnection portion 704. The metallization portion 706 includes a plurality of metallization interconnects 765, a plurality of under bump metallization interconnects 767 and a dielectric layer 762. The plurality of metallization interconnects 765 are coupled to the plurality of die interconnects 742. The plurality of metallization interconnects 765 may include a plurality of redistribution interconnects. The plurality of under bump metallization interconnects 767 are coupled to the plurality of metallization interconnects 765. The plurality of solder interconnects 708 are coupled to the plurality of under bump metallization interconnects 767.

The metallization portion 706 may be optional. In such instances, the plurality of solder interconnects 708 may be coupled to the plurality of die interconnects 742 (e.g., directly coupled to pad interconnects from the plurality of die interconnects 742).

The inductor 202 and the inductor 204 may be implemented in the integrated device 700. In some implemented, the inductor 202 and the inductor 204 are both implemented in the interconnection portion 704 of the integrated device 700. In some implemented, the inductor 202 and the inductor 204 are both implemented in the metallization portion 706 of the integrated device 700. In some implemented, the inductor 202 is implemented in the interconnection portion 704 of the integrated device 700, and the inductor 204 is implemented in the metallization portion 706. In some implemented, the inductor 204 is implemented in the interconnection portion 704 of the integrated device 700, and the inductor 202 is implemented in the metallization portion 706. In some implementations, the inductor 202 and/or the inductor 204 may be implemented on the back side of the die substrate 702. The integrated device 700 may be coupled to a substrate (e.g., 102) or a board (e.g., 108). In some implementations, there may be a plurality of pillar interconnects between the plurality of solder interconnects 708 and the plurality of under bump metallization interconnects 767.

In some implementations, the inductor via 262 and/or the inductor via 264 as described in FIG. 4, may be implemented as through substrate vias in a die substrate. In some implementations, the inductor via 262 and/or the inductor via 264 as described in FIG. 4, may be implemented as vias in die interconnection portion of an integrated device. In some implementations, the inductor via 262 and/or the inductor via 264 as described in FIG. 4, may be implemented as vias in a metallization portion. In some implementations, the inductor via 262 and/or the inductor via 264 as described in FIG. 4, may be implemented as vias in a substrate. In some implementations, the inductor via 262 and/or the inductor via 264 as described in FIG. 4, may be implemented as vias in a board. In some implementations, the inductor via 262 and/or the inductor via 264 as described in FIG. 4, may be replaced with or used in conjunction with solder interconnects and/or pillar interconnects.

FIG. 8 illustrates a package 800 that includes an integrated device 103, a metallization portion 802 and an encapsulation layer 806. The metallization portion 802 includes at least one dielectric layer 820 and a plurality of metallization interconnects 822. The metallization portion 802 may include a redistribution portion. The package 800 is coupled to the board 108 through a plurality of solder interconnects 101.

The inductor 202 and the inductor 204 may be implemented in the integrated device 103 of the package 800. In some implemented, the inductor 202 and the inductor 204 are both implemented in the metallization portion 802 of the package 800. In some implemented, the inductor 202 is implemented in the integrated device 103, and the inductor 204 is implemented in the metallization portion 802 of the package 800. In some implemented, the inductor 204 is implemented in the integrated device 103, and the inductor 202 is implemented in the metallization portion 802 of the package 800. In some implementations, the inductor 202 and the inductor 204 may be implemented in the integrated device 103 and the metallization portion 802.

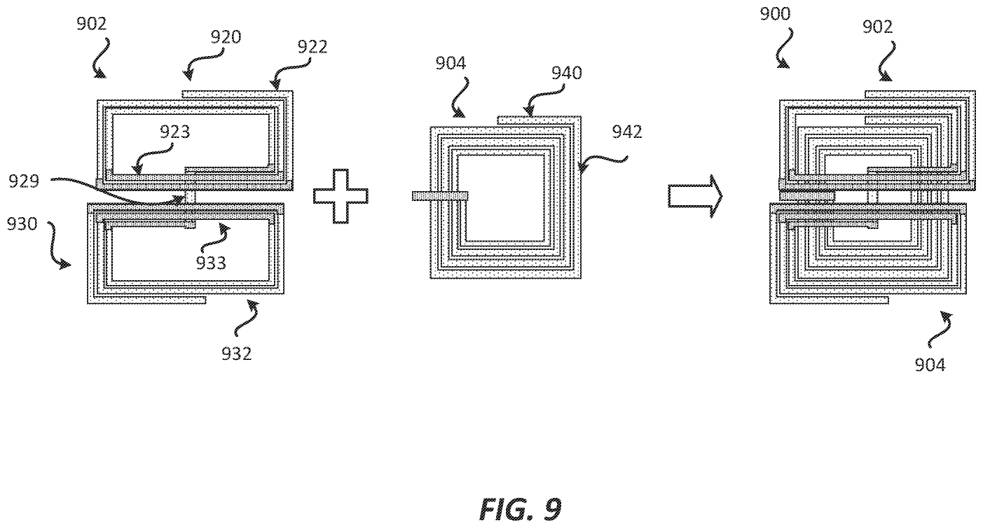

As mentioned above, different implementations may have different designs and/or configurations for inductors. FIGS. 9-13 illustrate other examples of inductors that may be implemented in a package, in a similar fashion as described for the inductor 202 and/or the inductor 204.

FIG. 9 illustrates a plan view of an inductor 902 and an inductor 904. The inductor 902 and the inductor 904 may be implemented such that at least parts of the inductor 902 laterally surround the inductor 904. The pair of inductors 900 includes the inductor 902 and the inductor 904. The inductor 902 includes a first spiral 920 and a second spiral 930. The first spiral 920 includes a first plurality of first spiral interconnects 922 and a second plurality of first spiral interconnects 923. The second spiral 930 includes a first plurality of second spiral interconnects 932 and a second plurality of second spiral interconnects 933. The first spiral 920 and the second spiral 930 are formed on two metal layers. The first plurality of first spiral interconnects 922 and the first plurality of second spiral interconnects 932 may be located on a first metal layer. The second plurality of first spiral interconnects 923 and the second plurality of second spiral interconnects 933 may be located on a second metal layer. The first spiral 920 may be coupled to the second spiral 930 through at least one inductor interconnect 929. For example, a first origin of the first spiral 920 may be coupled to a second origin of the second spiral 930 through at least one inductor interconnect 929. The at least one inductor interconnect 929 may be located on a first metal layer. It is noted that interconnects (of one or more inductors) on different metal layers may be coupled together through one or more vias (not shown) between metal layers.

The inductor 904 includes a spiral 940. The spiral 940 includes a plurality of spiral interconnects 942 located on a metal layer (e.g., first metal layer). Part of the inductor 904 may be located on the same metal layer as part of the inductor 902. FIG. 9 illustrates that the first plurality of first spiral interconnects 922 and the first plurality of second spiral interconnects 932 (from the inductor 902) laterally surround the plurality of spiral interconnects 942 from the inductor 904.

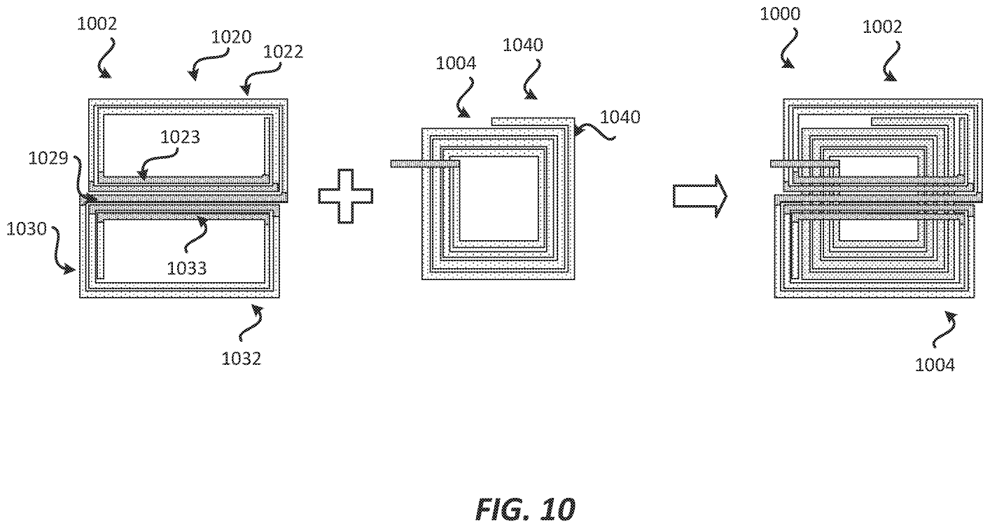

FIG. 10 illustrates a plan view of an inductor 1002 and an inductor 1004. The inductor 1002 and the inductor 1004 may be implemented such that the inductor 1002 laterally surround the inductor 1004. The pair of inductors 1000 include the inductor 1002 and the inductor 1004. The inductor 1002 includes a first spiral 1020 and a second spiral 1030. The first spiral 1020 includes a first plurality of first spiral interconnects 1022 and a second plurality of first spiral interconnects 1023. The second spiral 1030 includes a first plurality of second spiral interconnects 1032 and a second plurality of second spiral interconnects 1033. The first spiral 1020 and the second spiral 1030 are formed on two metal layers. The first plurality of first spiral interconnects 1022 and the first plurality of second spiral interconnects 1032 may be located on a first metal layer. The second plurality of first spiral interconnects 1023 and the second plurality of second spiral interconnects 1033 may be located on a second metal layer. The first spiral 1020 may be coupled to the second spiral 1030 through at least one inductor interconnect 1029. For example, a first tail terminal of the first spiral 1020 may be coupled to a second tail terminal of the second spiral 1030 through at least one inductor interconnect 1029. The at least one inductor interconnect 1029 may be located on a second metal layer. It is noted that interconnects (of one or more inductors) on different metal layers may be coupled together through one or more vias (not shown) between metal layers.

The inductor 1004 includes a spiral 1040. The spiral 1040 includes a plurality of spiral interconnects 1042 located on a metal layer (e.g., first metal layer). Part of the inductor 1004 may be located on the same metal layer as part of the inductor 1002. FIG. 10 illustrates that the first plurality of first spiral interconnects 1022 and the first plurality of second spiral interconnects 1032 (from the inductor 1002) laterally surround the plurality of spiral interconnects 1042 from the inductor 1004.

In some implementations, an electrical current may travel through the inductor 1002 through an electrical path that includes a first origin of the first spiral 1020, a first tail of the first spiral 1020, a first tail terminal of the first spiral 1020, at least one inductor interconnect 1029, a second tail terminal of the second spiral 1030, a second tail of the second spiral 1030, and a second origin of the second spiral 1030. In some implementations, a current may enter through the first origin of the first spiral 1020 and exit through the second origin of the second spiral 1030. In some implementations, a current may enter through the second origin of the second spiral 1030 and exit through the first origin of the first spiral 1020.

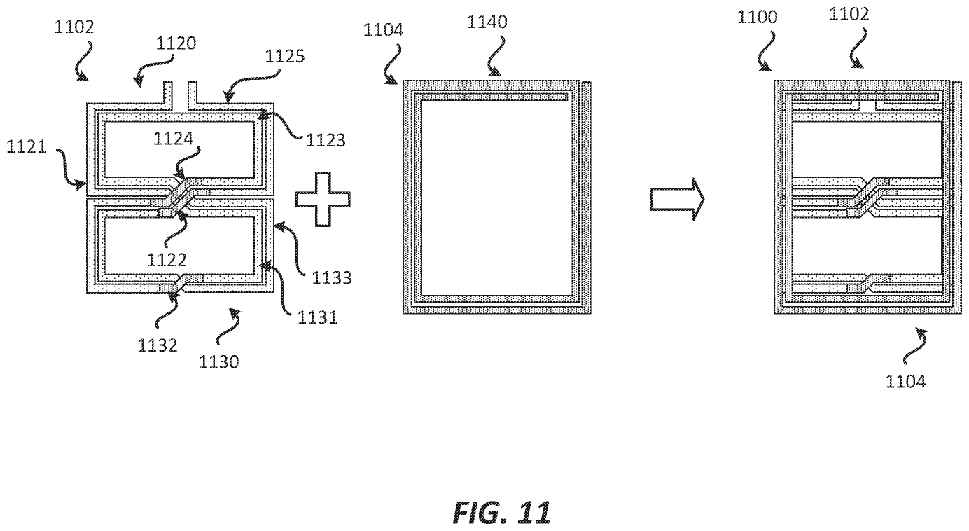

FIG. 11 illustrates a plan view of an inductor 1102 and an inductor 1104. The inductor 1102 and the inductor 1104 may be implemented such that the inductor 1102 vertically overlaps with the inductor 1104. The combination of the inductor 1102 and the inductor 1104 may be configured to operate as a transformer. In some implementations, a current traveling through the inductor 1102 may induce a current in the inductor 1104. In some implementations, a current traveling through the inductor 1104 may induce a current in the inductor 1102.

The pair of inductors 1100 includes the inductor 1102 and the inductor 1104. The inductor 1102 includes a first spiral 1120 and a second spiral 1130. The first spiral 1120 and the second spiral 1130 are intertwined. The first spiral 1120 and the second spiral 1130 are formed on two metal layers. The first spiral 1120 includes a first plurality of first spiral interconnects on a first metal layer and a second plurality of first spiral interconnects on a second metal layer. The second spiral 1130 includes a first plurality of second spiral interconnects on the first metal layer and a second plurality of second spiral interconnects on the second metal layer. It is noted that interconnects (of one or more inductors) on different metal layers may be coupled together through one or more vias (not shown) between metal layers. The spiral 1120 and the spiral 1130 are intertwined back and forth through several crossings (e.g., 1122, 1124, 1132) to form a figure 8-shaped windings, coils and/or turns. Thus, for example (i) a first portion 1121 of the spiral 1120 is coupled to and touching a first portion 1131 of the spiral 1130, (ii) a first portion 1131 of the spiral 1130 is coupled to and touching a second portion 1123 of the spiral 1120, (iii) a second portion 1123 of the spiral 1120 is coupled to and touching a second portion 1133 of the spiral 1130, and (iv) a second portion 1133 of the spiral 1130 is coupled to and touching a third portion 1125 of the spiral 1120.

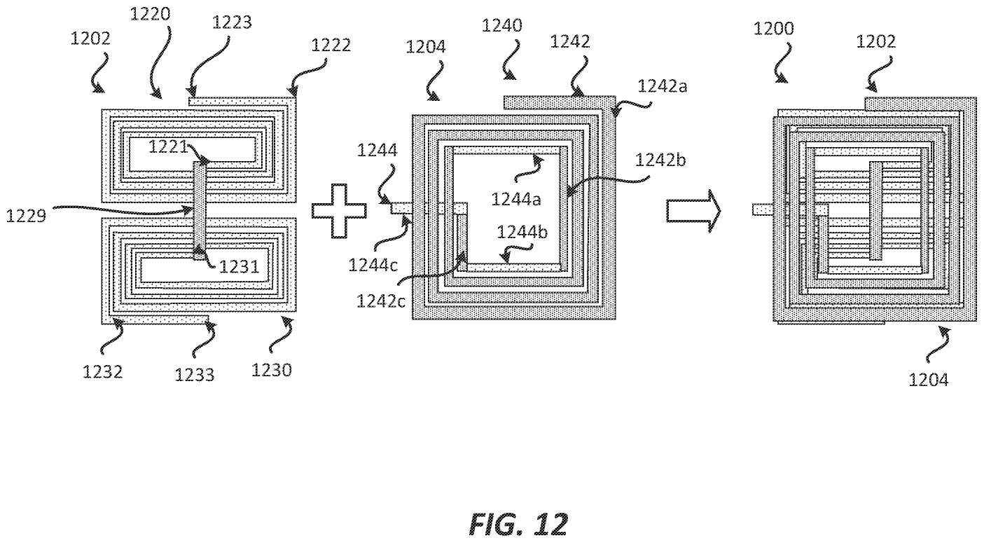

The inductor 1104 includes a spiral 1140. The spiral 1140 includes a plurality of spiral interconnects located on a metal layer (e.g., second metal layer). Part of the inductor 1104 may be located on the same metal layer as part of the inductor 1102. FIG. 12 illustrates a plan view of an inductor 1202 and an inductor 1204. As

shown in FIG. 12, the inductor 1202 may vertically overlap with the inductor 1204. The combination of the inductor 1202 and the inductor 1204 may be configured to operate as a transformer. In some implementations, a current traveling through the inductor 1202 may induce a current in the inductor 1204. In some implementations, a current traveling through the inductor 1204 may induce a current in the inductor 1202.

The inductor 1202 includes a first spiral 1220. The first spiral 1220 may include a first origin 1221, a first tail 1222 and a first tail terminal 1223. The first origin 1221 may be a first nucleus of the first spiral 1220. The first origin 1221 may be a first terminal for the first spiral 1220. The first tail terminal 1223 may be a second terminal for the first spiral 1220. The first spiral 1220, the first origin 1221, the first tail 1222 and the first tail terminal 1223 may be defined by one or more first spiral interconnects. For example, a first spiral interconnect may define and/or represent the first spiral 1220. A first portion of the first spiral interconnect may represent the first origin 1221. A second portion of the first spiral interconnect may represent the first tail 1222. A third portion of the first spiral interconnect may represent the first tail terminal 1223. In some implementations, the first spiral 1220 may have a first rotational direction (e.g., counter clockwise).

The inductor 1202 includes a second spiral 1230. The second spiral 1230 may include a second origin 1231, a second tail 1232 and a second tail terminal 1233. The second origin 1231 may be a second nucleus of the second spiral 1230. The second origin 1231 may be a first terminal for the second spiral 1230. The second tail terminal 1233 may be a second terminal for the second spiral 1230. The second spiral 1230, the second origin 1231, the second tail 1232 and the second tail terminal 1233 may be defined by one or more second spiral interconnects. For example, a second spiral interconnect may define and/or represent the second spiral 1230. A first portion of the second spiral interconnect may represent the second origin 1231. A second portion of the second spiral interconnect may represent the second tail 1232. A third portion of the second spiral interconnect may represent the second tail terminal 1233. In some implementations, the second spiral 1230 may have a first rotational direction (e.g., counter clockwise). The first spiral 1220 of the inductor 1202 may be coupled to the second spiral 1230 of the inductor 1202 through at least one inductor interconnect 1229. The at least one inductor interconnect 1229 may be an underpass or an overpass between the spiral 1220 and the spiral 1230 of the inductor 1202. Thus, the inductor 1202 may have an underpass or an overpass from an inner turn to an outer turn of the inductor 1202, and/or from an outer turn to an inner turn of the inductor 1202.

The inductor 1204 includes a spiral 1240. The spiral 1240 of the inductor 1204 may be located on two or more metal layers. Thus, the spiral 1240 may be defined by a plurality of spiral interconnects that are located on two or more metal layers. It is noted that interconnects (of one or more inductors) on different metal layers may be coupled together through one or more vias (not shown) between metal layers. The inductor 1204 includes a plurality of spiral interconnects 1242 and a plurality of spiral interconnects 1244. The spiral 1240 may include the plurality of spiral interconnects 1242 and the plurality of spiral interconnects 1244. The plurality of spiral interconnects 1242 includes a spiral interconnect 1242a, a spiral interconnect 1242b and a spiral interconnect 1242c. The plurality of spiral interconnects 1244 includes a spiral interconnect 1244a, a spiral interconnect 1244b and a spiral interconnect 1244c. The plurality of spiral interconnects 1242 may be located on a different metal layer from the plurality of spiral interconnects 1244. The spiral interconnect 1242a is coupled to the spiral interconnect 1244a (through a via interconnect). The spiral interconnect 1244a is coupled to the spiral interconnect 1242b (through a via interconnect). The spiral interconnect 1242b is coupled to the spiral interconnect 1244b (through a via interconnect). The spiral interconnect 1244b is coupled to the spiral interconnect 1242c (through a via interconnect). The spiral interconnect 1242c is coupled to the spiral interconnect 1244c (through a via interconnect). The inductor 1204 may be located between two portions of the inductor 1202. For example, the inductor 1204 may be located over the spiral 1220 of the inductor 1202 and below the spiral 1230 of the inductor 1202.

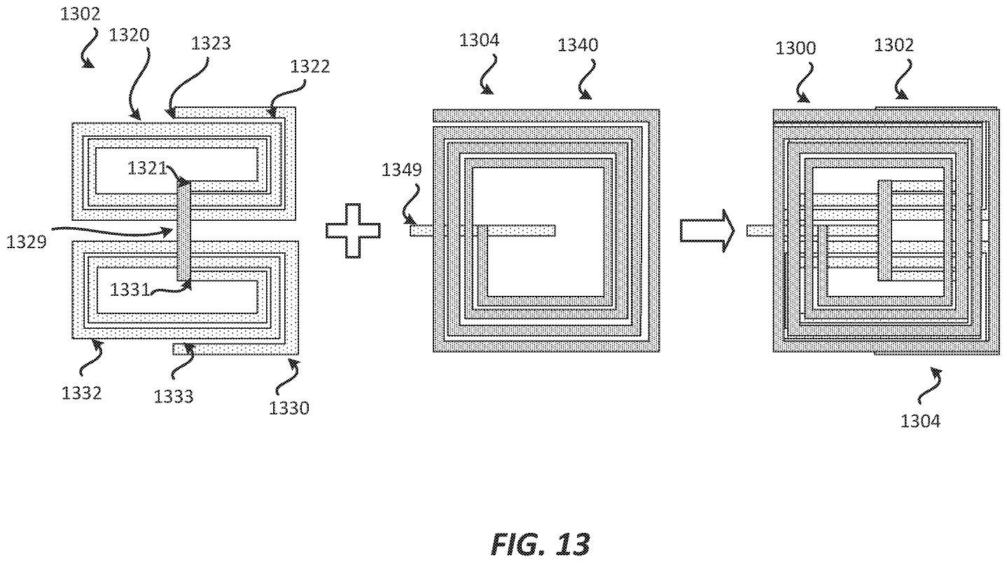

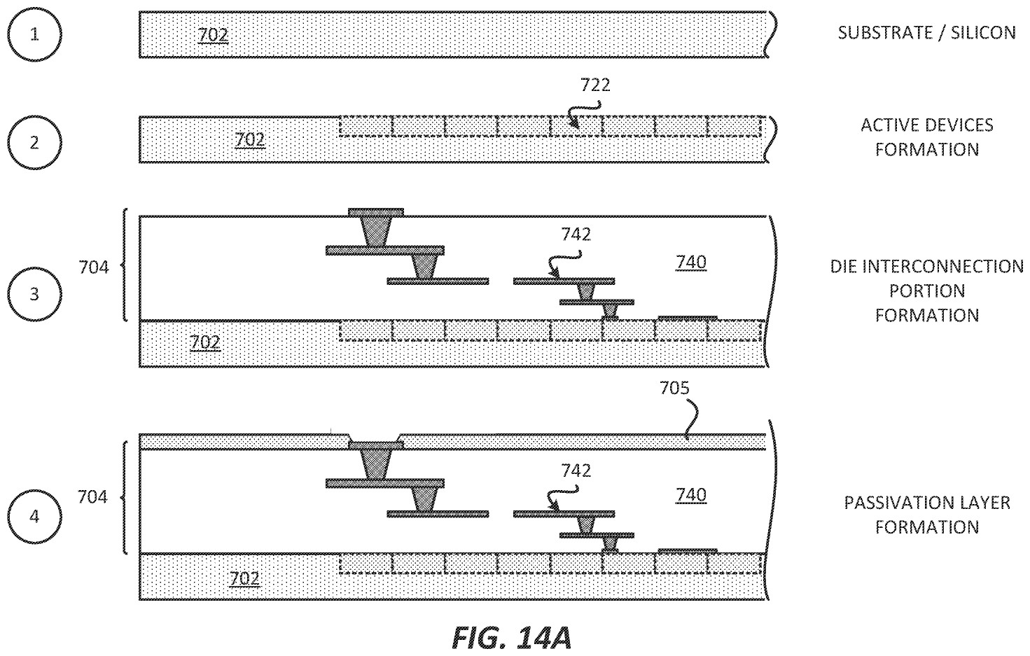

FIG. 13 illustrates a plan view of an inductor 1302 and an inductor 1304. As shown in FIG. 13, the inductor 1302 may vertically overlap with the inductor 1304. The inductor 1302 includes a first spiral 1320. The first spiral 1320 may include a first origin 1321, a first tail 1322 and a first tail terminal 1323. The first origin 1321 may be a first nucleus of the first spiral 1320. The first origin 1321 may be a first terminal for the first spiral 1320. The first tail terminal 1323 may be a second terminal for the first spiral 1320. The first spiral 1320, the first origin 1321, the first tail 1322 and the first tail terminal 1323 may be defined by one or more first spiral interconnects. For example, a first spiral interconnect may define and/or represent the first spiral 1320. A first portion of the first spiral interconnect may represent the first origin 1321. A second portion of the first spiral interconnect may represent the first tail 1322. A third portion of the first spiral interconnect may represent the first tail terminal 1323. In some implementations, the first spiral 1320 may have a first rotational direction (e.g., counter clockwise).

The inductor 1302 includes a second spiral 1330. The second spiral 1330 may include a second origin 1331, a second tail 1332 and a second tail terminal 1333. The second origin 1331 may be a second nucleus of the second spiral 1330. The second origin 1331 may be a first terminal for the second spiral 1330. The second tail terminal 1333 may be a second terminal for the second spiral 1330. The second spiral 1330, the second origin 1331, the second tail 1332 and the second tail terminal 1333 may be defined by one or more second spiral interconnects. For example, a second spiral interconnect may define and/or represent the second spiral 1330. A first portion of the second spiral interconnect may represent the second origin 1331. A second portion of the second spiral interconnect may represent the second tail 1332. A third portion of the second spiral interconnect may represent the second tail terminal 1333. In some implementations, the second spiral 1330 may have a second rotational direction (e.g., clockwise). The first spiral 1320 of the inductor 1302 may be coupled to the second spiral 1340 of the inductor 1302 through at least one inductor interconnect 1329. For example, the first origin 1321 of the first spiral 1320 of the inductor 1302 may be coupled to the second origin 1331 of the second spiral 1330 of the inductor 1302 through at least one inductor interconnect 1329.

The inductor 1304 includes a spiral 1340. The spiral 1340 of the inductor 1304 may be located on a metal layer. The spiral 1340 may be defined by a plurality of spiral interconnects that are located on a metal layer. An at least one inductor interconnect 1349 is coupled to an origin from the spiral 1340. The at least one inductor interconnect 1329 may be coupled to the at least one inductor interconnect 1349. It is noted that interconnects (of one or more inductors) on different metal layers may be coupled together through one or more vias (not shown) between metal layers.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 103, 105, 107) may include at least one electronic circuit (e.g., first electronic circuit, second electronic circuit, etc. . . . ). An integrated device may include transistors. An integrated device may be an example of an electrical component and/or electrical device. In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes.

FIGS. 9-13 illustrate examples of inductors and/or pairs of inductors that may be implemented in different parts of a package. As mentioned above, the inductors of FIGS. 9-13 may be implemented in an integrated device, a substrate and/or a board. For example, the inductors of FIGS. 9-13 may be implemented in various parts of the integrated device of FIG. 7 and/or the various parts of the package of FIG. 8. Any of the inductors described in the disclosure may have different designs, including different spirals, different numbers of turns, different windings, different crossings and/or different underpasses/overpasses. The number of turns in the spiral in the inductors shown in the disclosure are exemplary. Different implementations may have inductors with spirals that have different numbers of turns. The designs of the inductors are not limited to what is shown in the figures of the disclosure. Different implementations may have different designs to form symmetrical inductors to achieve a mutual inductance of zero (0) or near zero. The first inductor and the second inductor described in the disclosure may have a mutual inductance (e.g., coefficient of coupling K) in a range of about 0-0.1. The inductors described in the disclosure may formed on two or more metal layers. In some implementations, a first inductor may be coupled to a second inductor in shunt and/or series. In some implementations, any of the first inductor and any of the second inductor from the disclosure may be configured as a transformer. It is noted that any of the inductors may be a first inductor, and/or any of the inductors may be a second inductor. Similarly, it is noted that any of the spirals may be a first spiral, and/or any of the spirals may be a second spiral. In some implementations, an inductor may be an inductor portion that is part of an inductor defined by one or more inductors and/or inductor portions.

A spiral of an inductor may be referred to as an inductor spiral. An origin of an inductor may be referred to as an inductor origin. The origin of an inductor may be an origin terminal (e.g., inductor origin terminal). A tail of an inductor may be referred to as an inductor tail. A tail terminal of an inductor may be referred to as an inductor tail terminal. In some implementations, the tail terminal of an inductor may be considered part of the tail of the inductor. A coil of an inductor may be similar and/or the same as a spiral of an inductor.

### Exemplary Sequence for Fabricating an Integrated Device

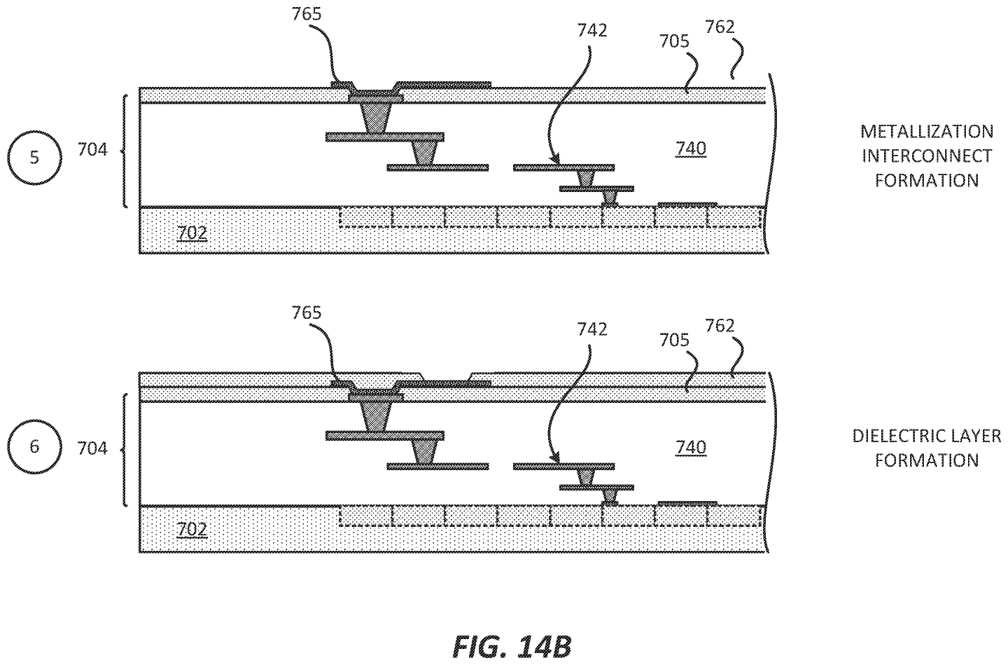

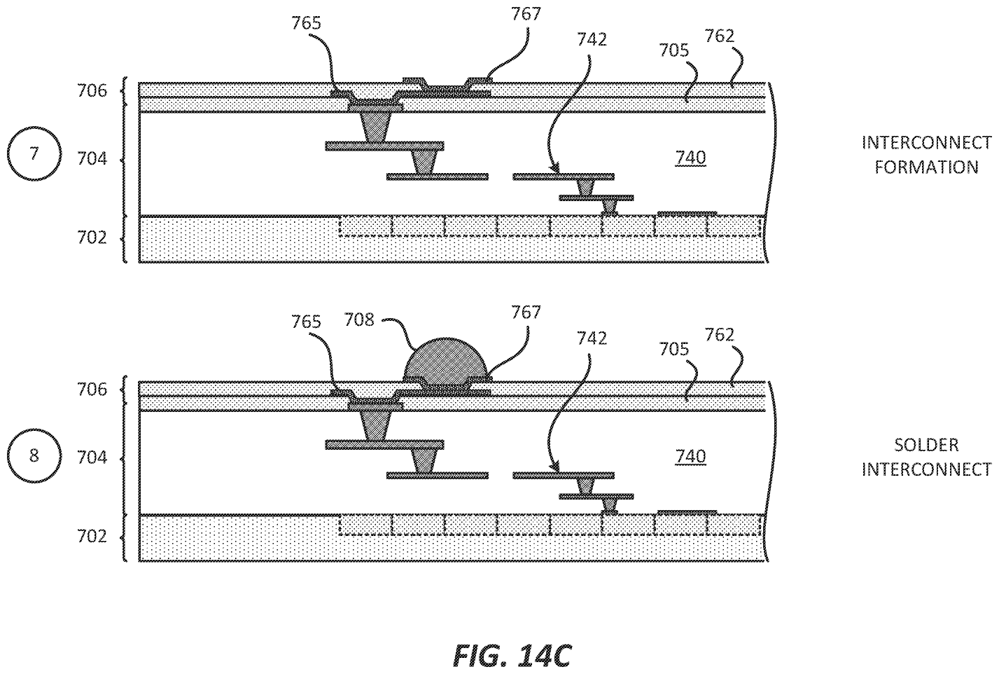

FIGS. 14A-14C illustrate an exemplary sequence for providing or fabricating an integrated device. In some implementations, the sequence of FIGS. 14A-14C may be used to provide or fabricate the integrated device 700 of FIG. 7, or any of the integrated devices described in the disclosure.

It should be noted that the sequence of FIGS. 14A-14C may combine one or more stages in order to simplify and/or clarify the sequence for providing or fabricating the integrated device. In some implementations, the order of the processes may be changed or modified. In some implementations, one or more of processes may be replaced or substituted without departing from the scope of the disclosure. The sequence of FIGS. 14A-14C may be used to fabricate one integrated device or several integrated devices at a time (as part of a wafer).

Stage 1, as shown in FIG. 14A illustrates a state after a die substrate 702 is provided. The die substrate 702 may include a wafer. The die substrate 702 may include silicon.

Stage 2 illustrates a state after a plurality of active devices are formed in and over the die substrate 702. The active devices may be part of the device level 722 of an integrated device. The plurality of active devices may include a plurality of cells (e.g., logic cells) and/or a plurality of transistors (not shown) that may be formed in and/or over the die substrate 702. The plurality of cells (e.g., logic cells) and/or a plurality of transistors (not shown) may be part of the device level 722 of the integrated device 700. Different implementations may use different types of transistors, such as a field effect transistor (FET), planar FET, finFET, and a gate all around FET. In some implementations, a front end of line (FEOL) process may be used to fabricate the plurality of cells (e.g., logic cells) and/or transistors in and/or over the die substrate 702.

Stage 3 illustrates a state after an interconnection portion 704 is formed. The interconnection portion 704 is located over and coupled to the die substrate 702. The interconnection portion 704 may be coupled to the plurality of cells and/or transistors located in and/or over the die substrate 702. The interconnection portion 704 (e.g., die interconnection portion) may include at least one dielectric layer 740 (e.g., die dielectric layer) and a plurality of die interconnects 742. The plurality of die interconnects 742 may be coupled to the plurality of cells and/or transistors. In some implementations, a back end of line (BEOL) process may be used to fabricate the interconnection portion 704.

Stage 4 illustrates a state after a passivation layer 705 is formed. The passivation layer 705 may be a dielectric layer. The passivation layer 705 may be considered part of the interconnection portion 704. The passivation layer 705 may be located over the at least one dielectric layer 740. A deposition and/or lamination process may be used to form the passivation layer 705.

Stage 5, as shown in FIG. 14B, illustrates a state after a plurality of metallization interconnects 765 are formed. The plurality of metallization interconnects 765 are coupled to a die interconnect from the plurality of die interconnects 742. A plating process may be used to form the plurality of metallization interconnects 765.

Stage 6 illustrates a state after a dielectric layer 762 is formed. The dielectric layer 762 may be located over the passivation layer 705 and the metallization interconnect 765. A deposition and/or lamination process may be used to form the dielectric layer 762.

Stage 7, as shown in FIG. 14C, illustrates a state after a plurality of under bump metallization interconnects 767 are formed. The plurality of under bump metallization interconnects 767 are coupled to metallization interconnect 765. A plating process may be used to form the plurality of under bump metallization interconnects 767. In some implementations, the plurality of metallization interconnects 765, the dielectric layer 762 and the plurality of under bump metallization interconnects 767 may be part of a metallization portion 706 of an integrated device.

Stage 8 illustrates a state after a plurality of solder interconnects 708 are coupled to the plurality of under bump metallization interconnects 767. A solder reflow process may be used to form the plurality of solder interconnects 708. The metallization portion 706 may be optional. In such instances, the plurality of solder interconnects 708 may be coupled to the plurality of die interconnects 742 (e.g., directly coupled to pad interconnects from the plurality of die interconnects 742).

Exemplary Flow Diagram of a Method for Fabricating an Integrated Device

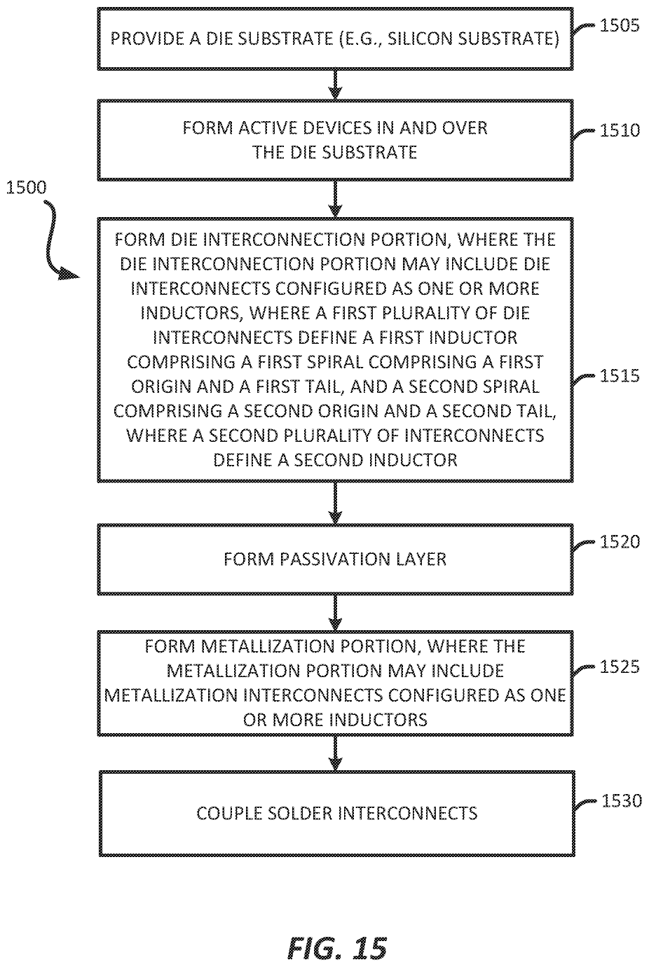

In some implementations, fabricating an integrated device includes several processes. FIG. 15 illustrates an exemplary flow diagram of a method 1500 for providing or fabricating an integrated device. In some implementations, the method 1500 of FIG. 15 may be used to provide or fabricate any of the integrated devices of the disclosure. For example, the method 1500 of FIG. 15 may be used to fabricate the integrated device 700.

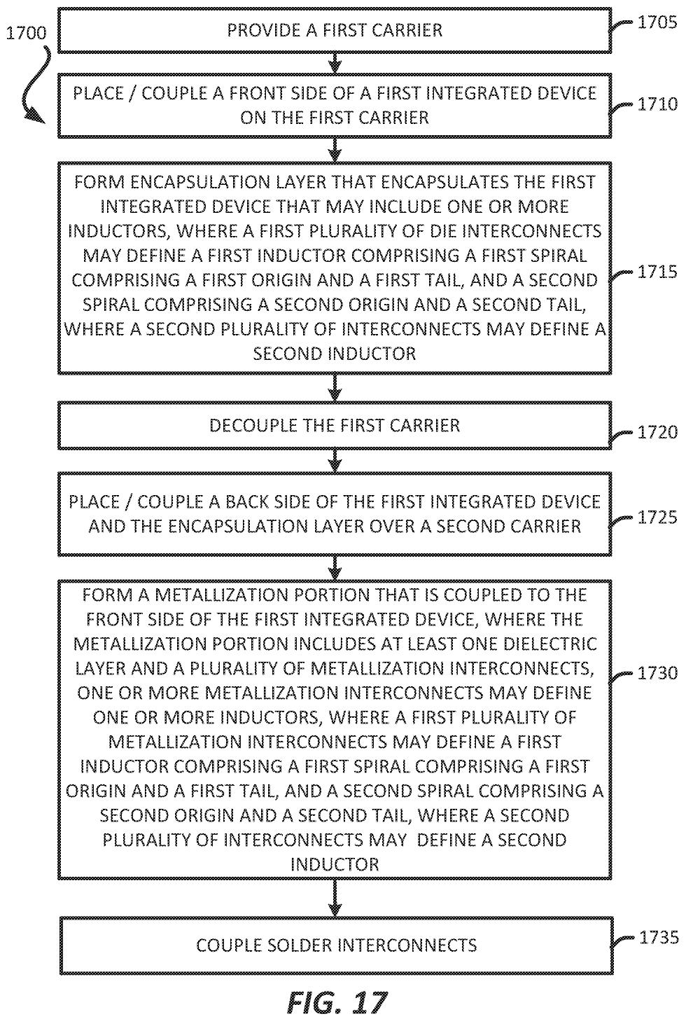

It should be noted that the method 1700 of FIG. 17 may combine one or more processes in order to simplify and/or clarify the method for providing or fabricating a package. In some implementations, the order of the processes may be changed or modified. In some implementations, one or more of processes may be replaced or substituted without departing from the scope of the disclosure. The method 1700 of FIG. 17 may be used to fabricate one integrated device or several integrated devices at a time (as part of a wafer).

The method provides (at 1505) a die substrate. Stage 1 of FIG. 14A, illustrates and describes an example of a die substrate 702 that is provided. The die substrate 702 may include a wafer. The die substrate 702 may include silicon.

The method forms (at 1510) form active devices in the and over the die substrate. Stage 2 of FIG. 14A, illustrates and describes an example of a plurality of active devices that are formed in and over the die substrate 702. The active devices may be part of the device level 722 of an integrated device. The plurality of active devices may include a plurality of cells (e.g., logic cells) and/or a plurality of transistors (not shown) that may be formed in and/or over the die substrate 702. The plurality of cells (e.g., logic cells) and/or a plurality of transistors (not shown) may be part of the device level 722 of the integrated device 700. Different implementations may use different types of transistors, such as a field effect transistor (FET), planar FET, finFET, and a gate all around FET. In some implementations, a front end of line (FEOL) process may be used to fabricate the plurality of cells (e.g., logic cells) and/or transistors in and/or over the die substrate 702.

The method forms (at 1515) a die interconnection portion that is coupled to the die substrate. Forming the die interconnection portion includes forming at least one dielectric layer and a plurality of die interconnects. Stage 3 of FIG. 14A, illustrates and describes an example of an interconnection portion 704 is formed. The interconnection portion 704 is located over and coupled to the die substrate 702. The interconnection portion 704 may be coupled to the plurality of cells and/or transistors located in and/or over the die substrate 702. The interconnection portion 704 (e.g., die interconnection portion) may include at least one dielectric layer 740 (e.g., die dielectric layer) and a plurality of die interconnects 742. The plurality of die interconnects 742 may be coupled to the plurality of cells and/or transistors. In some implementations, a back end of line (BEOL) process may be used to fabricate the interconnection portion 704.

The method forms (at 1520) a passivation layer. Stage 4 of FIG. 14A, illustrates and describes an example of a passivation layer 705 that is formed. The passivation layer 705 may be a dielectric layer. The passivation layer 705 may be considered part of the interconnection portion 704. The passivation layer 705 may be located over the at least one dielectric layer 740. A deposition and/or lamination process may be used to form the passivation layer 705.

The method forms (at 1525) a metallization portion that is coupled to the die interconnection portion. Forming the metallization portion may include forming a plurality of metallization interconnects, at least one dielectric layer and/or a plurality of under bump metallization interconnects. Stage 5 of FIG. 14B, illustrates and describes an example of a plurality of metallization interconnects 765 that are formed. The plurality of metallization interconnects 765 are coupled to a die interconnect from the plurality of die interconnects 742. A plating process may be used to form the plurality of metallization interconnects 765. Stage 6 of FIG. 14B, illustrates and describes an example of a dielectric layer 762 that is formed. The dielectric layer 762 may be located over the passivation layer 705 and the plurality of metallization interconnects 765. A deposition and/or lamination process may be used to form the dielectric layer 762. Stage 7 of FIG. 14C, illustrates and describes an example of a plurality of under bump metallization interconnects 767 that are formed. The plurality of under bump metallization interconnects 767 are coupled to the plurality of metallization interconnects 765. A plating process may be used to form the plurality of under bump metallization interconnects 767. In some implementations, the plurality of metallization interconnects 765, the dielectric layer 762 and the plurality of under bump metallization interconnects 767 may be part of a metallization portion 706 of an integrated device.

The method couples (at 1530) a plurality of solder interconnects to a metallization portion. Stage 8 of FIG. 14C, illustrates and describes an example of a plurality of solder interconnects 708 that are coupled to the plurality of under bump metallization interconnects 767. A solder reflow process may be used to form the plurality of solder interconnects 708. The metallization portion 706 may be optional. In such instances, the plurality of solder interconnects 708 may be coupled to the plurality of die interconnects 742 (e.g., directly coupled to pad interconnects from the plurality of die interconnects 742).

### Exemplary Sequence for Fabricating a Package Comprising an Integrated Device and a Metallization Portion

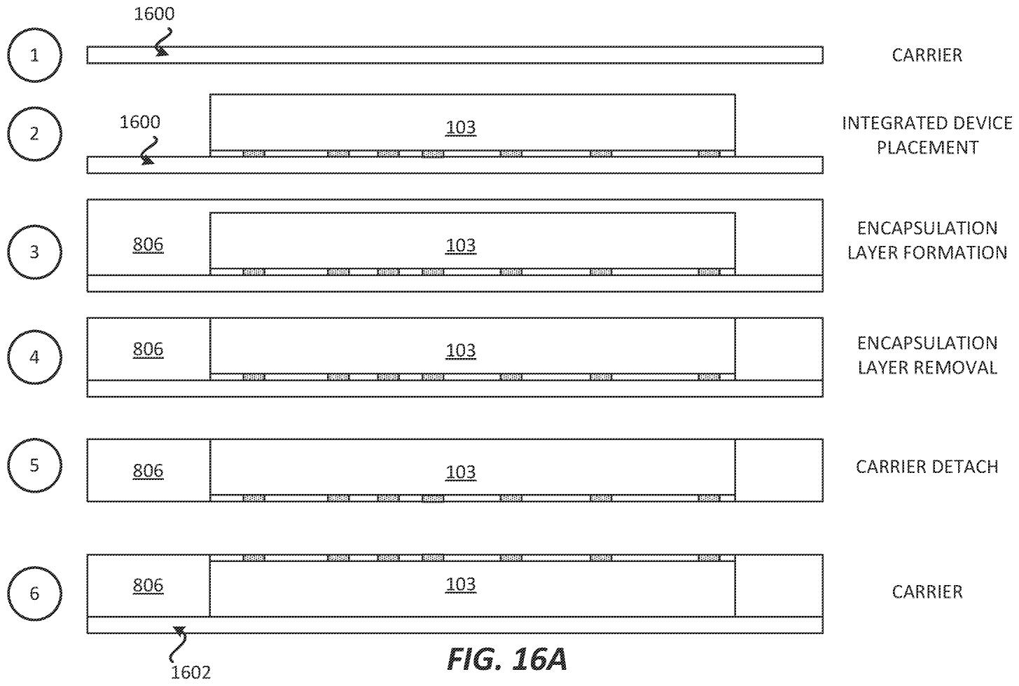

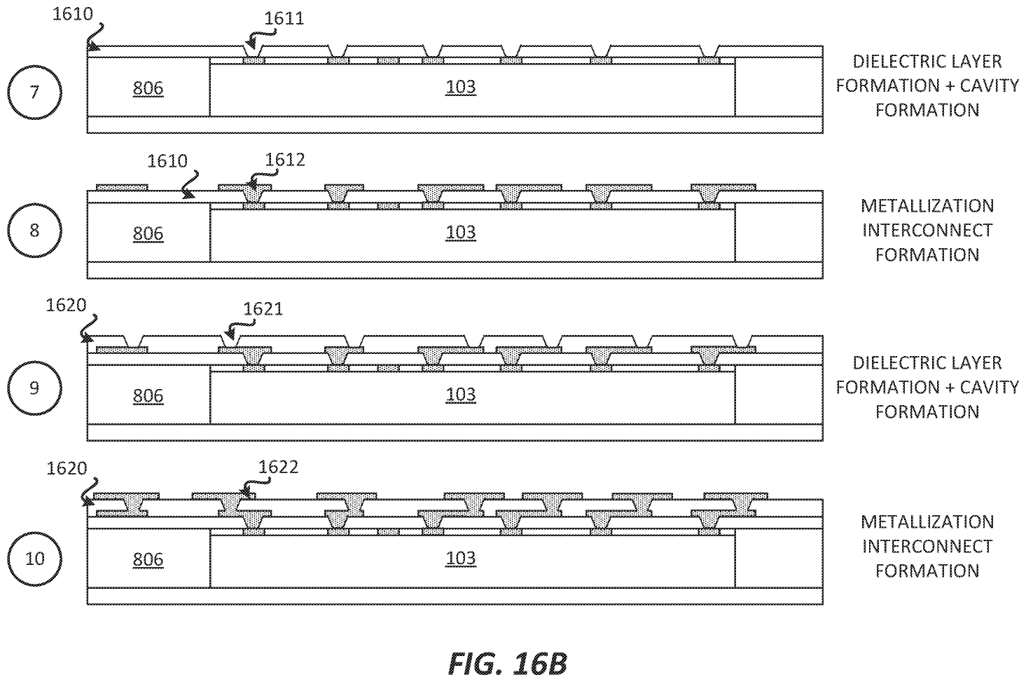

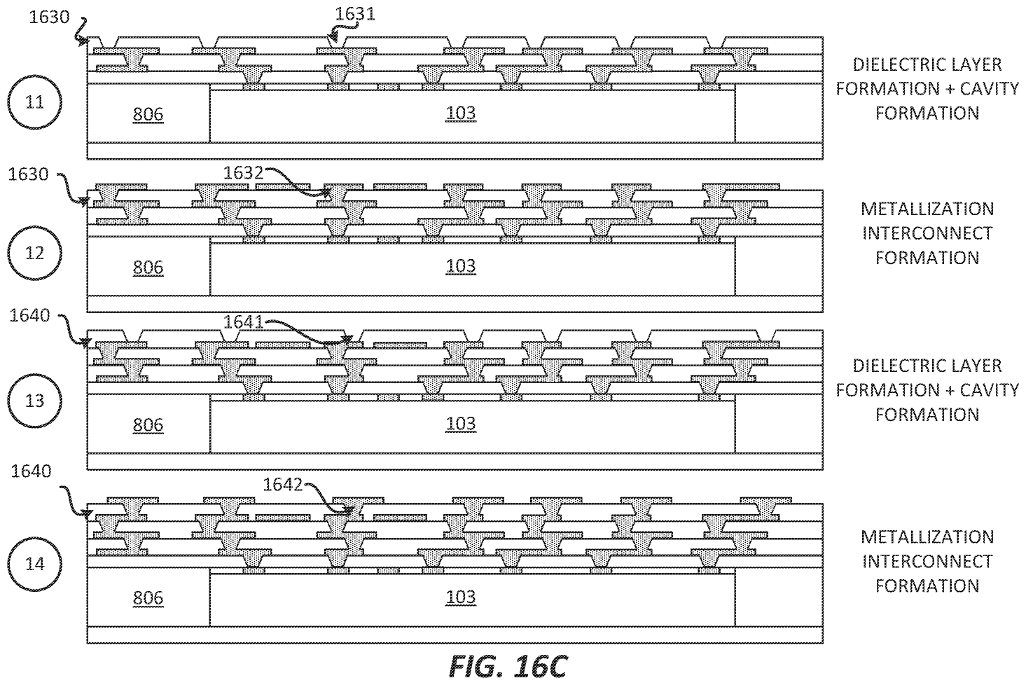

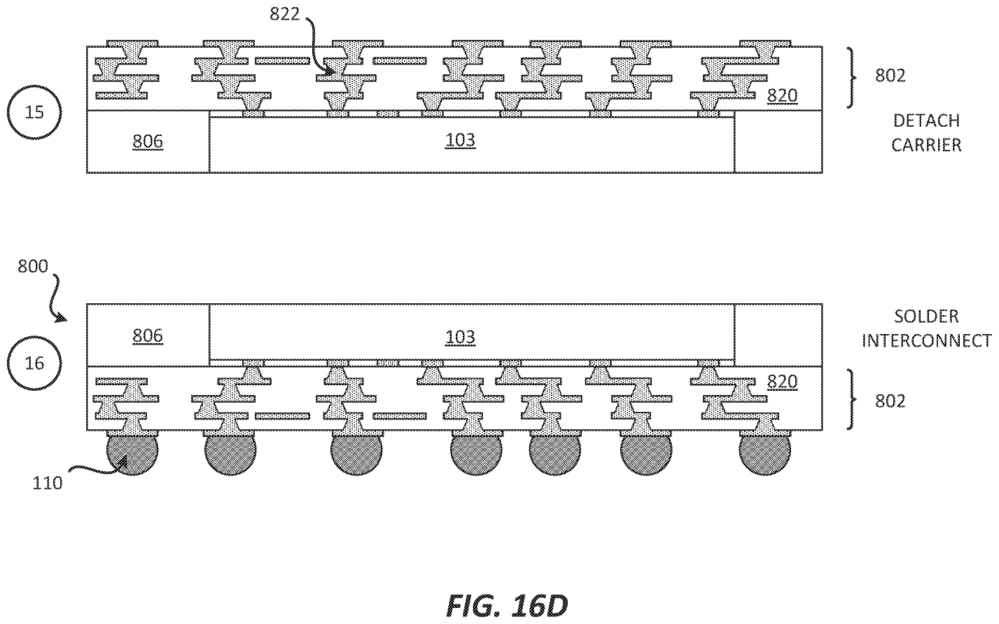

FIGS. 16A-16D illustrate an exemplary sequence for providing or fabricating a package that includes an integrated device and a metallization portion. In some implementations, the sequence of FIGS. 16A-16D may be used to provide or fabricate the package 800 of FIG. 8, or any of the packages described in the disclosure.

It should be noted that the sequence of FIGS. 16A-16D may combine one or more stages in order to simplify and/or clarify the sequence for providing or fabricating the package. In some implementations, the order of the processes may be changed or modified. In some implementations, one or more of processes may be replaced or substituted without departing from the scope of the disclosure. The sequence of FIGS. 16A-16D may be used to fabricate one package or several packages at a time (as part of a wafer).

Stage 1, as shown in FIG. 16A illustrates a state after a carrier 1600. An adhesive coat/layer may be provided over a surface of the carrier 1600.

Stage 2 illustrates a state after an integrated device 103 is placed on the carrier 1600. A pick and place process may be used to place the integrated device. The front side of the integrated device 103 may be placed on the carrier 1600. In some implementations, more than one integrated device may be placed on the carrier 1600. In some implementations, the integrated device 103 may include one or more inductors as described in the disclosure.

Stage 3 illustrates a state after an encapsulation layer 106 is formed over the carrier 1600 and the integrated device 103. The encapsulation layer 106 may encapsulate the integrated device 103. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process.

Stage 4 illustrates a state after portions of the encapsulation layer 106 may be removed. A grinding process may be used to remove a top portion of the encapsulation layer 106 and/or a back side of the integrated device 103.

Stage 5 illustrates a state after the carrier 1600 is decoupled from the integrated device 103 and the encapsulation layer 106. The carrier 1600 may be detached from the integrated device 103 and the encapsulation layer 106.

Stage 6 illustrates the integrated device 103 and the encapsulation layer 106 are placed on a carrier 1602. The back side of the integrated device 103 may be placed and coupled to the carrier 1602. There may be an adhesive coat on the carrier 1602. A pick and place process may be used to place the integrated device 103 and the encapsulation layer 106 on the carrier 1602.

Stage 7, as shown in FIG. 16B, illustrates a state after a dielectric layer 1610 is formed over the integrated device 103 and the encapsulation layer 106. A deposition and/or a lamination process may be used to form the dielectric layer 1610. The dielectric layer 1610 may be formed over a front side of the integrated device 103. Stage 7 also illustrates a state after a plurality of cavities 1611 are formed in the dielectric layer 1610. The plurality of cavities 1611 may be formed using an etching process (e.g., photo etching process). A masking process, an exposure process and/or a development process may be used to form the plurality of cavities 1611. The plurality of cavities 1611 may be formed over the plurality of die interconnects of the integrated device 103, such that the plurality of die interconnects are exposed.

Stage 8 illustrates a state after metallization interconnects are formed in and over surfaces of the dielectric layer 1610 and in the plurality of cavities 1611. A plurality of metallization interconnects 1612 may be formed over (e.g., above) a first surface of the dielectric layer 1610 and the plurality of cavities 1611. A masking process, a plating process, an exposure process, a development process and/or an etching process may be used to form the plurality of metallization interconnects 1612.

Stage 9 illustrates a state after a dielectric layer 1620 is formed over the dielectric layer 1610 and the plurality of metallization interconnects 1612. A deposition and/or a lamination process may be used to form the dielectric layer 1620. Stage 9 also illustrates a state after a plurality of cavities 1621 are formed in the dielectric layer 1620. The plurality of cavities 1621 may be formed using an etching process (e.g., photo etching process). A masking process, an exposure process and/or a development process may be used to form the plurality of cavities 1621. The plurality of cavities 1621 may be formed over the plurality of metallization interconnects 1612, such that portions of the plurality of metallization interconnects 1612 are exposed.

Stage 10 illustrates a state after metallization interconnects are formed in and over surfaces of the dielectric layer 1620 and in the plurality of cavities 1621. A plurality of metallization interconnects 1622 may be formed over (e.g., above) a first surface of the dielectric layer 1620 and the plurality of cavities 1621. A masking process, a plating process, an exposure process, a development process and/or an etching process may be used to form the plurality of metallization interconnects 1622. The plurality of metallization interconnects 1622 may be coupled to the plurality of metallization interconnects 1612.

Stage 11, as shown in FIG. 16C, illustrates a state after a dielectric layer 1630 is formed over the dielectric layer 1630 and the plurality of metallization interconnects 1622. A deposition and/or a lamination process may be used to form the dielectric layer 1630. Stage 11 also illustrates a state after a plurality of cavities 1631 are formed in the dielectric layer 1630. The plurality of cavities 1631 may be formed using an etching process (e.g., photo etching process). A masking process, an exposure process and/or a development process may be used to form the plurality of cavities 1631. The plurality of cavities 1631 may be formed over the plurality of metallization interconnects 1622, such that portions of the plurality of metallization interconnects 1622 are exposed.

Stage 12 illustrates a state after metallization interconnects are formed in and over surfaces of the dielectric layer 1630 and in the plurality of cavities 1631. A plurality of metallization interconnects 1632 may be formed over (e.g., above) a first surface of the dielectric layer 1630 and the plurality of cavities 1631. A masking process, a plating process, an exposure process, a development process and/or an etching process may be used to form the plurality of metallization interconnects 1632. The plurality of metallization interconnects 1632 may be coupled to the plurality of metallization interconnects 1622.

Stage 13 illustrates a state after a dielectric layer 1640 is formed over the dielectric layer 1640 and the plurality of metallization interconnects 1632. A deposition and/or a lamination process may be used to form the dielectric layer 1640. Stage 13 also illustrates a state after a plurality of cavities 1641 are formed in the dielectric layer 1640. The plurality of cavities 1641 may be formed using an etching process (e.g., photo etching process). A masking process, an exposure process and/or a development process may be used to form the plurality of cavities 1641. The plurality of cavities 1641 may be formed over the plurality of metallization interconnects 1632, such that portions of the plurality of metallization interconnects 1632 are exposed.

Stage 14 illustrates a state after metallization interconnects are formed in and over surfaces of the dielectric layer 1640 and in the plurality of cavities 1641. A plurality of metallization interconnects 1642 may be formed over (e.g., above) a first surface of the dielectric layer 1640 and the plurality of cavities 1641. A masking process, a plating process, an exposure process, a development process and/or an etching process may be used to form the plurality of metallization interconnects 1642. The plurality of metallization interconnects 1642 may be coupled to the plurality of metallization interconnects 1632.

Stage 15 illustrates a state after the carrier 1602 is decoupled from the integrated device 103 and the encapsulation layer 106. The carrier 1602 may be detached from the integrated device 103 and the encapsulation layer 106. The dielectric layer 820 may represent the dielectric layer 1610, the dielectric layer 1620, the dielectric layer 1630 and/or the dielectric layer 1640. The plurality of metallization interconnects 822 may represent the plurality of metallization interconnects 1612, the plurality of metallization interconnects 1622, the plurality of metallization interconnects 1632 and/or the plurality of metallization interconnects 1642. In some implementations, the metallization portion 802 may include one or more inductors as described in the disclosure.

Stage 16 illustrates a state after a plurality of solder interconnects 110 are coupled to the metallization portion 802. A solder reflow process may be used to couple the plurality of solder interconnects 110 to the plurality of metallization interconnects 822 of the metallization portion 802.

### Exemplary Flow Diagram of a Method for Fabricating a Package Comprising an Integrated Device and a Metallization Portion

In some implementations, fabricating a package includes several processes. FIG. 17 illustrates an exemplary flow diagram of a method 1700 for providing or fabricating a package. In some implementations, the method 1700 of FIG. 17 may be used to provide or fabricate any of the packages of the disclosure. For example, the method 1700 of FIG. 17 may be used to fabricate the package 800.

It should be noted that the method 1700 of FIG. 17 may combine one or more processes in order to simplify and/or clarify the method for providing or fabricating a package. In some implementations, the order of the processes may be changed or modified. In some implementations, one or more of processes may be replaced or substituted without departing from the scope of the disclosure. The method 1700 of FIG. 17 may be used to fabricate one package or several packages at a time (as part of a wafer).

The method provides (at 1705) a carrier. In some implementations, the carrier may be provided with an adhesive. Stage 1 of FIG. 16A, illustrates and describes an example of providing a carrier 1600. An adhesive coat/layer may be located over a surface of the carrier 1600.

The method places (at 1710) a front side of an integrated device over the carrier. In some implementations, the front side of the integrated device is placed over a carrier that includes and adhesive. In some implementations, more than one integrated device may be placed over the carrier. Stage 2 of FIG. 16A, illustrates and describes an example of an integrated device 103 that is placed on the carrier 1600. A pick and place process may be used to place the integrated device. The front side of the integrated device 103 may be placed on the carrier 1600. In some implementations, more than one integrated device may be placed on the carrier 1600. In some implementations, the integrated device 103 may include one or more inductors as described in the disclosure.

The method forms (at 1715) an encapsulation layer that encapsulates the integrated device. The encapsulation layer may be coupled to the integrated device and the carrier. Stage 3 of FIG. 16A, illustrates and describes an example of an encapsulation layer 106 that is formed over the carrier 1600 and the integrated device 103. The encapsulation layer 106 may encapsulate the integrated device 103. The encapsulation layer 106 may include a mold, a resin and/or an epoxy. The encapsulation layer 106 may be a means for encapsulation. The encapsulation layer 106 may be provided by using a compression and transfer molding process, a sheet molding process, or a liquid molding process. In some implementations, once the encapsulation layer 106 is provided, portions of the encapsulation layer 106 may be removed. For example, a grinding process may be used to remove a top portion of the encapsulation layer 106 and/or a back side of the integrated device 103. Stage 4 of FIG. 16A illustrates and describes an example of removing a portion of the encapsulation layer 106.

The method decouples (at 1720) the carrier from the encapsulation layer and the integrated device. Stage 5 of FIG. 16A, illustrates and describes an example of the carrier 1600 that is decoupled from the integrated device 103 and the encapsulation layer 106. The carrier 1600 may be detached from the integrated device 103 and the encapsulation layer 106.

The method places (at 1725) a back side of the integrated device and the encapsulation layer over another carrier (e.g., second carrier). The carrier may include an adhesive. Stage 6 of FIG. 16B, illustrates and describes an example of the integrated device 103 and the encapsulation layer 106 that are placed on a carrier 1602. The back side of the integrated device 103 may be placed and coupled to the carrier 1602. There may be an adhesive coat on the carrier 1602. A pick and place process may be used to place the integrated device 103 and the encapsulation layer 106 on the carrier 1602.

The method forms (at 1730) a metallization portion that is coupled to the front side of the integrated device and the encapsulation layer. The metallization portion may include at least one dielectric layer and a plurality of metallization interconnects. The plurality of metallization interconnects may include a first metallization interconnect on a first metal layer and a second metallization interconnect on a first metal layer, where the second interconnect has a second thickness that is different from a first thickness of the first metallization interconnect. Forming the metallization portion may include forming at least one dielectric layer and forming include a first metallization interconnect on a first metal layer and a second metallization interconnect on a first metal layer. The second interconnect may have a second thickness that is different from a first thickness of the first metallization interconnect. Stage 7 of FIG. 16B through Stage 15 of FIG. 16D illustrate examples of forming a metallization portion that is coupled to at least one integrated device. Different implementations may have different numbers of metal layers. Once the metallization portion is formed (at 1730), the method may decouple the second carrier from the integrated device and the encapsulation layer. In some implementations, the metallization portion 802 may include one or more inductors as described in the disclosure.

The method couples (at 1735) a plurality of solder interconnects to the metallization interconnects of the metallization portion. Stage 16 of FIG. 16D, illustrates and describes an examples of a plurality of solder interconnects 110 that are coupled to the metallization portion 802. A solder reflow process may be used to couple the plurality of solder interconnects 110 to the plurality of metallization interconnects 822 of the metallization portion 802.

### Exemplary Electronic Devices

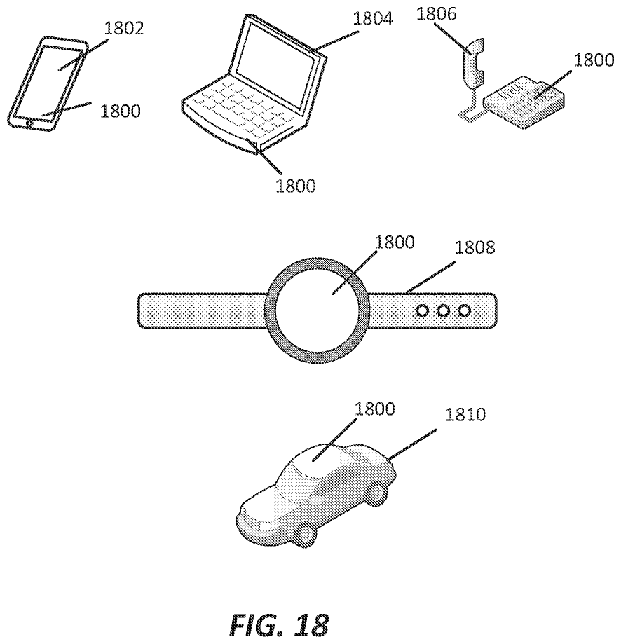

FIG. 18 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1802, a laptop computer device 1804, a fixed location terminal device 1806, a wearable device 1808, or automotive vehicle 1810 may include a device 1800 as described herein. The device 1800 may be, for example, any of the devices and/or integrated circuit (IC) packages described herein. The devices 1802, 1804, 1806 and 1808 and the vehicle 1810 illustrated in FIG. 18 are merely exemplary. Other electronic devices may also feature the device 1800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-13, 14A-14C, 15, 16A-16D and 17-18 may be rearranged and/or combined into a single component, process, feature or function or embodied in several components, processes, or functions. Additional elements, components, processes, and/or functions may also be added without departing from the disclosure. It should also be noted FIGS. 1-13, 14A-14C. 15, 16A-16D and 17-18 and its corresponding description in the present disclosure is not limited to dies and/or ICs. In some implementations, FIGS. 1-13, 14A-14C, 15, 16A-16D and 17-18 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: An integrated device comprising a die substrate; and a die interconnection portion coupled to the die substrate, wherein the die interconnection comprises a first inductor and a second inductor. The first inductor comprises a first spiral comprising a first origin and a first tail; and a second spiral comprising a second origin and a second tail.

Aspect 2: The integrated device of aspect 1, wherein the first spiral and the second spiral form a figure 8-shaped inductor.

Aspect 3: The integrated device of aspects 1 through 2, wherein the first inductor further comprises at least one inductor interconnect coupled to the first origin of the first spiral and the second origin of the second spiral.

Aspect 4: The integrated device of aspect 3, wherein the at least one inductor interconnect comprises: a first via coupled to the first origin of the first spiral; a die interconnect coupled to the first via, wherein the die interconnect is located on a second metal layer of the die interconnection portion; and a second via coupled to the die interconnect and the second original of the second spiral.

Aspect 5: The integrated device of aspects 1 through 4, wherein the first tail of the first spiral is coupled to the second tail of the second spiral.

Aspect 6: The integrated device of aspects 1 through 4, wherein the first tail of the first spiral winds in a first rotational direction, and wherein the second tail of the second spiral winds in the first rotational direction.

Aspect 7: The integrated device of aspects 1 through 4, wherein the first tail of the first spiral winds in a first rotational direction, and wherein the second tail of the second spiral winds in a second rotational direction that is opposite to the first rotational direction.

Aspect 8: The integrated device of aspect 7, wherein the first rotational direction is a counter clockwise direction, and wherein the first rotational direction is a clockwise direction.

Aspect 9: The integrated device of aspects 1 through 8, wherein the first inductor is coupled to the second inductor in shunt and/or in series.

Aspect 10: The integrated device of aspects 1 through 9, wherein the second inductor includes a second spiral inductor.

Aspect 11: The integrated device of aspects 1 through 10, wherein the first inductor and the second inductor are configured as a transformer.

Aspect 12: The integrated device of aspects 1 through 11, wherein the second inductor is located in the die interconnection portion, and wherein the second inductor is located above the first inductor.

Aspect 13: The integrated device of aspects 1 through 11, wherein the second inductor is located below the first inductor.

Aspect 14: The integrated device of aspects 1 through 13, wherein the first inductor laterally surrounds the second inductor.

Aspect 15: The integrated device of aspects 1 through 14, wherein the first spiral comprises at least one first interconnect, and wherein the second spiral comprises at least one second interconnect.

Aspect 16: A device comprising a first inductor and a second inductor. The first inductor comprises a first spiral comprising a first origin and a first tail; and a second spiral comprising a second origin and a second tail, wherein the first spiral and the second spiral form a figure 8-shaped inductor.

Aspect 17: The device of aspect 16, wherein the device comprises an integrated device that includes a plurality of die interconnects, wherein the first inductor is formed based on a first plurality of die interconnects from the plurality of die interconnects of the integrated device, and wherein the second inductor is formed based on a second plurality of die interconnects from the plurality of die interconnects of the integrated device.

Aspect 18: The device of aspect 16, wherein the device comprises: an integrated device that includes a plurality of die interconnects, and a substrate comprising a plurality of interconnects, and wherein the first inductor is formed based on die interconnects from the plurality of die interconnects of the integrated device, and wherein the second inductor is formed based on interconnects from the plurality of interconnects of the substrate.

Aspect 19: The device of aspect 16, wherein the device comprises: an integrated device that includes a plurality of die interconnects, and a substrate comprising a plurality of interconnects, and wherein the first inductor is formed based on interconnects from the plurality of interconnects of the substrate, and wherein the second inductor is formed based on die interconnects from the plurality of die interconnects of the integrated device.

Aspect 20: The device of aspect 16, wherein the device comprises: an integrated device that includes a plurality of die interconnects, and a metallization portion comprising a plurality of metallization interconnects, and wherein the first inductor is formed based on die interconnects from the plurality of die interconnects of the integrated device, wherein the second inductor is formed based on metallization interconnects from the plurality of metallization interconnects of the metallization portion.

Aspect 21: The device of aspect 16, wherein the device comprises: an integrated device that includes a plurality of die interconnects, and a metallization portion comprising a plurality of metallization interconnects, and wherein the first inductor is formed based on metallization interconnects from the plurality of metallization interconnects of the metallization portion, and wherein the second inductor is formed based on die interconnects from the plurality of die interconnects of the integrated device,

Aspect 22: The device of aspect 16, wherein the first inductor further comprises at least one inductor interconnect coupled to the first origin of the first spiral and the second origin of the second spiral.

Aspect 23: The device of aspect 22, wherein the at least one inductor interconnect comprises: a first via coupled to the first origin of the first spiral; a die interconnect coupled to the first via, wherein the die interconnect is located on a second metal layer of the die interconnection portion; and a second via coupled to the die interconnect and the second original of the second spiral.

Aspect 24: The device of aspects 16 through 23, wherein the first tail of the first spiral is coupled to the second tail of the second spiral.

Aspect 25: The device of aspects 16 through 24, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 26: A method for fabricating an integrated device, comprising: providing a die substrate; forming a die interconnection portion coupled to the die substrate, wherein forming the die interconnection portion includes forming a plurality of die interconnects, wherein the plurality of die interconnects comprises: a first plurality die interconnects that define a first inductor comprising: a first spiral comprising a first origin and a first tail; and a second spiral comprising a second origin and a second tail; and a second plurality of die interconnects that define a second inductor.

Aspect 27: The method of aspect 26, wherein the first spiral and the second spiral form a figure 8-shaped inductor.

Aspect 28: The method of aspects 26 through 27, wherein the first tail of the first spiral is coupled to the second tail of the second spiral.

Aspect 29: The method of aspects 26 through 28, wherein the first inductor is coupled to the second inductor in shunt and/or in series.

Aspect 30: A method comprising: providing a die substrate; forming a die interconnection portion coupled to the die substrate, wherein forming the die interconnection portion includes forming a plurality of die interconnects, wherein the plurality of die interconnects comprises: a first plurality interconnects that define a first inductor comprising: a first spiral comprising a first origin and a first tail; and a second spiral comprising a second origin and a second tail; and forming a metallization portion that comprises a plurality of metallization interconnects, wherein the plurality of metallization interconnects comprises a first plurality of metallization interconnects that define a second inductor.

Aspect 31: The method of aspect 30, wherein the first spiral and the second spiral form a figure 8-shaped inductor.

Aspect 32: The method of aspects 30 through 31, wherein the first tail of the first spiral is coupled to the second tail of the second spiral.

Aspect 33: The method of aspects 30 through 32, wherein the first inductor is coupled to the second inductor in shunt and/or in series.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a die substrate; and
a die interconnection portion coupled to the die substrate, wherein the die interconnection comprises a first inductor comprising:
a first spiral comprising a first origin and a first tail; and
a second spiral comprising a second origin and a second tail; and
a second inductor.

2. The integrated device of claim 1, wherein the first spiral and the second spiral form a figure 8-shaped inductor.

3. The integrated device of claim 1, wherein the first inductor further comprises at least one inductor interconnect coupled to the first origin of the first spiral and the second origin of the second spiral.

4. The integrated device of claim 3, wherein the at least one inductor interconnect comprises:
a first via coupled to the first origin of the first spiral;
a die interconnect coupled to the first via, wherein the die interconnect is located on a second metal layer of the die interconnection portion; and
a second via coupled to the die interconnect and the second original of the second spiral.

5. The integrated device of claim 1, wherein the first tail of the first spiral is coupled to the second tail of the second spiral.

6. The integrated device of claim 1,
wherein the first tail of the first spiral winds in a first rotational direction, and
wherein the second tail of the second spiral winds in the first rotational direction.

7. The integrated device of claim 1,
wherein the first tail of the first spiral winds in a first rotational direction, and
wherein the second tail of the second spiral winds in a second rotational direction that is opposite to the first rotational direction.

8. The integrated device of claim 7,
wherein the first rotational direction is a counter clockwise direction, and
wherein the first rotational direction is a clockwise direction.

9. The integrated device of claim 1, wherein the first inductor is coupled to the second inductor in shunt and/or in series.

10. The integrated device of claim 1, wherein the second inductor includes a second spiral inductor.

11. The integrated device of claim 1, wherein the first inductor and the second inductor are configured as a transformer.

12. The integrated device of claim 1,
wherein the second inductor is located in the die interconnection portion, and
wherein the second inductor is located above the first inductor.

13. The integrated device of claim 1, wherein the second inductor is located below the first inductor.

14. The integrated device of claim 1, wherein the first inductor laterally surrounds the second inductor.

15. The integrated device of claim 1,
wherein the first spiral comprises at least one first interconnect, and
wherein the second spiral comprises at least one second interconnect.

16. A device comprising:
a first inductor comprising:
a first spiral comprising a first origin and a first tail; and
a second spiral comprising a second origin and a second tail, wherein the first spiral and the second spiral form a figure 8-shaped inductor; and
a second inductor.

17. The device of claim 16,
wherein the device comprises an integrated device that includes a plurality of die interconnects,
wherein the first inductor is formed based on a first plurality of die interconnects from the plurality of die interconnects of the integrated device, and
wherein the second inductor is formed based on a second plurality of die interconnects from the plurality of die interconnects of the integrated device.

18. The device of claim 16,
wherein the device comprises:
an integrated device that includes a plurality of die interconnects, and
a substrate comprising a plurality of interconnects,
wherein the first inductor is formed based on die interconnects from the plurality of die interconnects of the integrated device, and
wherein the second inductor is formed based on interconnects from the plurality of interconnects of the substrate.

19. The device of claim 16,
wherein the device comprises:
an integrated device that includes a plurality of die interconnects, and
a substrate comprising a plurality of interconnects,
wherein the first inductor is formed based on interconnects from the plurality of interconnects of the substrate, and
wherein the second inductor is formed based on die interconnects from the plurality of die interconnects of the integrated device.

20. The device of claim 16,
wherein the device comprises:
an integrated device that includes a plurality of die interconnects, and
a metallization portion comprising a plurality of metallization interconnects,
wherein the first inductor is formed based on die interconnects from the plurality of die interconnects of the integrated device, and
wherein the second inductor is formed based on metallization interconnects from the plurality of metallization interconnects of the metallization portion.

21. The device of claim 16,
wherein the device comprises:
an integrated device that includes a plurality of die interconnects, and
a metallization portion comprising a plurality of metallization interconnects,
wherein the first inductor is formed based on metallization interconnects from the plurality of metallization interconnects of the metallization portion, and
wherein the second inductor is formed based on die interconnects from the plurality of die interconnects of the integrated device.

22. The device of claim 16, wherein the first inductor further comprises at least one inductor interconnect coupled to the first origin of the first spiral and the second origin of the second spiral.

23. The device of claim 22, wherein the at least one inductor interconnect comprises:
a first via coupled to the first origin of the first spiral;
a die interconnect coupled to the first via, wherein the die interconnect is located on a second metal layer of the die interconnection portion; and
a second via coupled to the die interconnect and the second original of the second spiral.

24. The device of claim 16, wherein the first tail of the first spiral is coupled to the second tail of the second spiral.

25. The device of claim 16, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IOT) device, and a device in an automotive vehicle.
